(19) United States
(12) Patent Application Publication
(10) Pub. No.: US 2024/0105482 A1
(43) Pub. Date: Mar. 28, 2024

(54) SUBSTRATE TREATING APPARATUS

(71) Applicant: SCREEN Holdings Co., Ltd., Kyoto (JP)

(72) Inventor: Ichiro MITSUYOSHI, Kyoto (JP)

(21) Appl. No.: 18/469,707

(22) Filed: Sep. 19, 2023

(30) Foreign Application Priority Data
Sep. 22, 2022 (JP) 2022-151707

(51) Int. Cl. H01L 21/677; B08B 3/04; H01L 21/67

(52) U.S. Cl. CPC H01L 21/67718; B08B 3/04; H01L 21/67023

(57) ABSTRACT

A posture turning unit of a substrate treating apparatus includes two horizontal holders configured to place a plurality of substrates when the substrates are in a horizontal posture, two vertical holders provided below the horizontal holders and configured to hold the substrates in a vertical posture when the substrates are in the vertical posture, an opening and closing portion configured to move the two vertical holders between a holding position and a passing position, a supporting portion configured to support the two horizontal holders and the two vertical holders, a longitudinal rotator configured to rotate the supporting portion around a horizontal axis so as to direct the two vertical holders to the horizontal substrate transport mechanism, and a moving unit configured to move the supporting portion and the longitudinal rotator. When a posture of the substrates is turned to horizontal, the opening and closing portion moves the two vertical holders to into the passing position.

### CROSS-REFERENCE TO RELATED APPLICATIONS

This application claims priority to Japanese Patent Application No. 2022-151707 filed Sep. 22, 2022, the subject matter of which is incorporated herein by reference in entirety.

### TECHNICAL FIELD

The present invention relates to a substrate treating apparatus configured to perform treatment on substrates. Examples of substrates include semiconductor substrates, substrates for flat panel displays (FPDs), glass substrates for photomasks, substrates for optical disks, substrates for magnetic disks, ceramic substrates, and substrates for solar cells. Examples of the FPDs include liquid crystal display devices and organic electroluminescence (EL) display devices.

### BACKGROUND ART

Examples of currently-used substrate treating apparatus include a substrate treating apparatus of a hybrid type provided with a batch-type processing module (batch processing unit) configured to perform treatment on a plurality of substrates collectively, and a single-wafer-type processing module (single-wafer processing unit) configured to perform treatment on the substrates treated by the batch-type processing module one by one. See, for example, Japanese Patent Publication (Translation of PCT Application) No. 2016-502275 and Japanese Unexamined Patent Publication No. 2021-064652.

The substrates on which the batch-type processing module performs the treatment are in a vertical posture. In contrast to this, the substrates on which the single-wafer module performs the treatment are in a horizontal posture. Accordingly, a rotating mechanism (posture turning mechanism) turns a posture of the substrates from vertical to horizontal.

Japanese Unexamined Patent Publication No. 2018-056341 discloses a substrate treating apparatus provided with a posture turning mechanism (posture turning unit or rotating mechanism).

### SUMMARY OF INVENTION

### Technical Problem

Japanese Patent Publication (Translation of PCT Application) 2016-502275 discloses an apparatus provided with a tank, a robot, and a rotating mechanism. The robot takes two substrates from the tank, and places the two substrates on the rotating mechanism. Thereafter, the rotating mechanism turns a posture of the two substrates to horizontal. That is, the rotating mechanism turns a posture of the substrates transported by the robot. Regarding this, the rotating mechanism (posture turning unit) may sometimes be used for turning a posture of the substrates that the rotating mechanism itself moves to receive.

Moreover, the posture turning unit may include a vertical holder configured to hold the substrates in a vertical posture, and the substrate treating apparatus may include a horizontal substrate transport mechanism configured to transport substrates in a horizontal posture, for example. In this case, the posture turning unit may sometimes be used for directing the vertical holder, i.e., a lower face of the vertical holder, to the horizontal substrate transport mechanism after the posture of the substrates is turned to horizontal. This is because the horizontal substrate transport mechanism accesses the posture turning unit from a side adjacent to the vertical holder.

The present invention has been made regarding the state of the art noted above, and its one object is to provide a substrate treating apparatus in which a posture turning unit turns a posture of substrates which the posture turning unit itself moves to receive, and in which a horizontal substrate transport mechanism is accessible to the posture turning unit from a side adjacent to a vertical holder, holding the substrates in a vertical posture, after the posture of the substrates is turned to horizontal.

### Solution to Problem

The present invention is constituted as stated below to achieve the above object. One aspect of the present invention provides a substrate treating apparatus for successively performing batch treatment for processing a plurality of substrates collectively and single-wafer treatment for processing the substrates one by one. The substrate treating apparatus includes a batch process tank configured to perform treatment on the plurality of substrates collectively, a batch substrate transport mechanism configured to transport the substrates in a vertical posture collectively to the batch process tank, a single-wafer processing chamber configured to perform treatment on the substrates one by one, a horizontal substrate transport mechanism configured to transport the substrates in a horizontal posture one by one to the single-wafer processing chamber, and a posture turning mechanism configured to turn a posture of the substrates, on which the batch treatment is performed, from vertical to horizontal. The posture turning mechanism includes a substrate holder configured to hold the substrates in the vertical posture that are transported by the batch substrate transport mechanism and arranged at a predetermined pitch, and a posture turning unit configured to receive the substrates from the substrate holder and turn the posture of the substrates from vertical to horizontal. The posture turning unit includes two horizontal holders configured to house two sides of each of the substrates opposite to each other in a radial direction and place the substrates thereon at the predetermined pitch when the substrates are in the horizontal posture, two vertical holders configured to house two sides of each of the substrates, and provided below the horizontal holders and configured to hold the substrates in the vertical posture when the substrates are in the vertical posture, an opening and closing portion configured to move the two vertical holders between a holding position where a gap between the two vertical holders is narrowed for holding the substrates with the two vertical holders and a passing position where the gap between the two vertical holders is widened for passing the substrates through the two vertical holders, a supporting portion configured to support the two horizontal holders and the two vertical holders, a longitudinal rotator configured to rotate the supporting portion around a horizontal axis so as to direct the two vertical holders to the horizontal substrate transport mechanism in order to turn the posture of the substrates from vertical to horizontal, and a moving unit configure to move the supporting portion and the longitudinal rotator between a substrate stand-by region where the substrate holder is arranged and a substrate posture turning region for turning the posture of the substrates from vertical to horizontal. The moving unit moves the supporting portion and the longitudinal rotator to the substrate stand-by region when the substrates in the vertical posture are held by the substrate holder, the two vertical holders are moved to the holding position by the opening and closing portion, whereby the two vertical holders hold the substrates in the vertical posture held by the substrate holder, whereas the two horizontal holders house the substrates held by the two vertical holders, the moving unit moves the supporting portion and the longitudinal rotator to the substrate posture turning region while the substrates are held by the two vertical holders, the longitudinal rotator rotates the supporting portion around the horizontal axis, thereby turning the posture of the substrates from vertical to horizontal, the opening and closing portion moves the two vertical holders into the passing position when the posture of the substrates is turned to horizontal, and the horizontal substrate transport mechanism takes the substrates in the horizontal posture one by one while the substrates pass between the two vertical holders moved into the passing position, and transports the taken substrates to the single-wafer processing chamber.

In the substrate treating apparatus according to the aspect of the present invention, the posture turning mechanism includes the substrate holder and the posture turning unit. The moving unit of the posture turning unit can move the supporting portion that supports the two horizontal holders and the two vertical holders. Moreover, the longitudinal rotator of the posture turning unit rotates the supporting portion around the horizontal axis. Accordingly, the posture turning unit can turn the posture of the substrates that the posture turning unit itself moves to receive. Moreover, the longitudinal rotator rotates the supporting portion around the horizontal axis so as to direct the two vertical holders to the horizontal substrate transport mechanism in order to turn a posture of the substrates from vertical to horizontal. Thereafter, the opening and closing portion moves the two vertical holders into the passing position. Accordingly, the horizontal substrate transport mechanism can transport the substrates from a side adjacent to the vertical holder.

Moreover, it is preferred in the aspect of the substrate treating apparatus described above that the posture turning unit further includes a lateral rotator configured to rotate the supporting portion around a rotary axis that is orthogonal to an alignment direction of the substrates and extends in a direction orthogonal to the horizontal axis, and that the moving unit moves the supporting portion, the lateral rotator, and the longitudinal rotator. The posture turning unit can turn a direction of front and back faces of the substrates at any timing after receiving the substrates from the substrate holder.

Moreover, it is preferred in the aspect of the substrate treating apparatus described above that the posture turning mechanism further includes a second lateral rotator configured to rotate the substrate holder around a vertical axis. The directions of the front and back faces of the substrates can be turned at a side adjacent to the substrate holder, achieving a simplified construction of the posture turning unit.

Moreover, it is preferred in the aspect of the substrate treating apparatus described above that the two vertical holders include plural-paired holding grooves for holding the substrates one by one and plural-paired passing grooves for passing the substrates one by one, that the plural-paired holding grooves and the plural-paired passing grooves are arranged alternately in pairs, that the two vertical holders are moved to the holding position by the opening and closing portion, whereby a first divided substrate group, made by taking every other substrate out of the substrates held by the substrate holder in the vertical posture, is held with the plural-paired holding grooves, and the two horizontal holders house the first divided substrate group. The two vertical holders can hold the first divided substrate group of the substrates in which the substrates are aligned spaced apart by the gap corresponding to the width of the substrates, obtaining a widened pitch between two adjacent substrates. Accordingly, the horizontal substrate transport mechanism can take the substrates from the posture turning unit easily.

Moreover, it is preferred in the aspect of the substrate treating apparatus described above that the posture turning mechanism further includes a stand-by tank configured to store a liquid in which the substrates held by the substrate holder is immersed. If the substrates are dried before the dry treatment in the single-wafer processing chamber, substrate pattern collapse occurs. However, the present invention can prevent drying of the substrates held by the substrate holder.

Moreover, it is preferred in the aspect of the substrate treating apparatus described above that the posture turning mechanism further includes a nozzle for the posture turning unit configured to supply a liquid in a shower state or in a mist state to the substrates held by the two vertical holders of the posture turning unit. If the substrates are dried before the dry treatment in the single-wafer processing chamber, substrate pattern collapse occurs. However, the present invention can prevent drying of the substrates held by the two vertical holders of the posture turning unit.

Moreover, it is preferred in the substrate treating apparatus described above that the moving unit is positioned higher than the substrates in the vertical posture held by the two vertical holders. Contamination due to falling of droplets from the wet substrates can be prevented in a driving unit, including the moving unit, of the posture turning unit. For example, failure due to a contaminated driving unit can be prevented.

Moreover, it is preferred in the substrate treating apparatus described above that the horizontal axis is positioned higher than the substrates in the vertical posture held by the two vertical holders, and the supporting portion supports the two horizontal holders and the two vertical holders via the two horizontal holders from a side opposite to the two vertical holders. Accordingly, the substrates held by the two vertical holders and the like can be moved close to the horizontal substrate transport mechanism when the longitudinal rotator rotates the supporting portion around the horizontal axis.

### Advantageous Effects of Invention

With the substrate treating apparatus in the present invention, the posture turning unit turns the posture of the substrates which the posture turning unit itself moves to receive, and the horizontal substrate transport mechanism is accessible to the posture turning unit from the side of the vertical holders, holding the substrates in the vertical posture, after the posture of the substrates is turned to horizontal.

### BRIEF DESCRIPTION OF DRAWINGS

For the purpose of illustrating the invention, there are shown in the drawings several forms which are presently preferred, it being understood, however, that the invention is not limited to the precise arrangement and instrumentalities shown.

FIG. 1 is a plan view schematically illustrating a configuration of a substrate treating apparatus according to a first embodiment of the present invention.

FIG. 2 is a side view of a substrate handling mechanism.

FIGS. 3A to 3F are each a side view illustrating a first posture turning mechanism (posture turning unit and pusher mechanism) in a transferring block.

FIG. 4A is a plan view of a second posture turning mechanism, and FIG. 4B is a front view of the second posture turning mechanism.

FIG. 5 is a front view illustrating two chucks of the posture turning unit (horizontal holder and vertical holder).

FIG. 6 is a flowchart illustrating operation of the substrate treating apparatus.

FIG. 7 is a flowchart illustrating operation of the second posture turning mechanism.

FIGS. 8A to 8C are each a front view illustrating the first-half operation of the second posture turning mechanism.

FIGS. 9A to 9C are each a plan view illustrating the first-half operation of the second posture turning mechanism.

FIGS. 10A to 10C are each a front view illustrating the second-half operation of the second posture turning mechanism.

FIGS. 11A to 11C are each a plan view illustrating the second-half operation of the second posture turning mechanism.

FIG. 12A is a plan view of a second posture turning mechanism according to a second embodiment, and FIG. 12B is a front view of the second posture turning mechanism according to the second embodiment.

FIG. 13A is a longitudinal sectional view of a lifter of a second posture turning mechanism according to a third embodiment, and FIG. 13B is a side view of a posture turning unit of the second posture turning mechanism according to the third embodiment.

FIG. 14 is a plan view schematically illustrating a configuration of a substrate treating apparatus according to the modification.

### FIRST EMBODIMENT

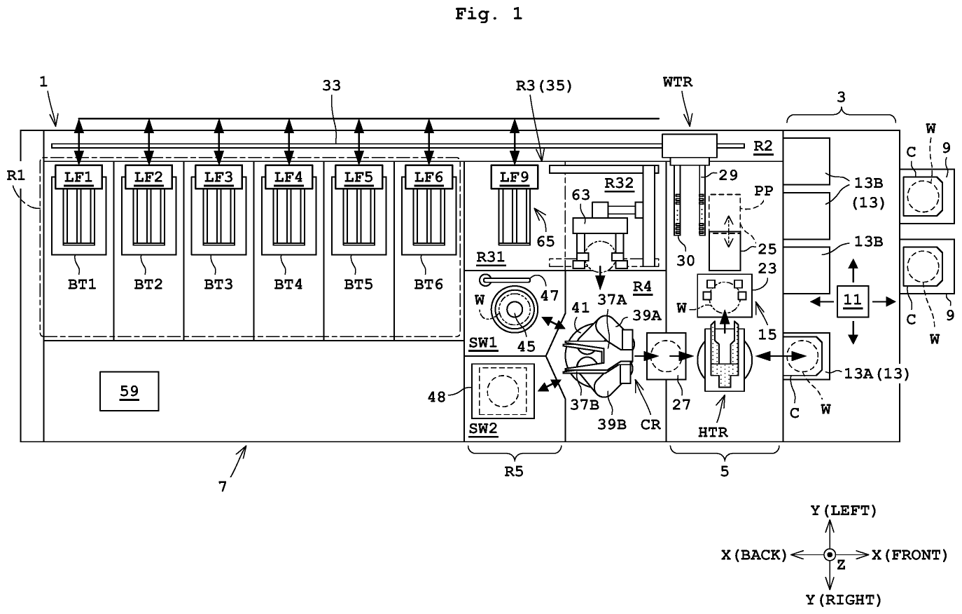

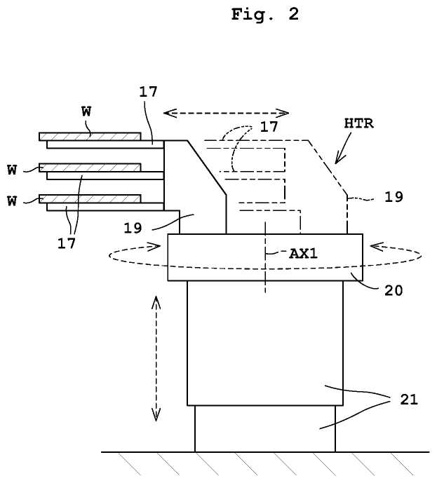

A first embodiment of the present invention will now be described with reference to the drawings. FIG. 1 is a plan view schematically illustrating a configuration of a substrate treating apparatus 1 according to a first embodiment of the present invention. FIG. 2 is a side view of a substrate handling mechanism HTR.

1. Overall Configuration

Reference is made to FIG. 1. The substrate treating apparatus 1 includes a stocker block 3, a transferring block 5, and a treating block 7. The stocker block 3, the transferring block 5, and the treating block 7 are arranged in this order in line in a horizontal direction.

The substrate treating apparatus 1 performs chemical liquid treatment, cleaning treatment, dry treatment, and the like, for example, on the substrates W. The substrate treating apparatus 1 successively performs batch treatment and single-wafer treatment to substrates W. That is, the substrate treating apparatus 1 performs the batch treatment to the substrates W, and then performs the single-wafer treatment to the substrates W. The batch treatment is a process system of performing treatment collectively on a plurality of substrates W. The single-wafer treatment is a process system of performing treatment on a plurality of substrates W one by one.

In the present specification, the direction in which the stocker block 3, the transferring block 5, and the treating block 7 are arranged is referred to as a “front-back direction X” for convenience. The front-back direction X is horizontal. One direction of the front-back direction X from the transferring block 5 to the stocker block 3 is referred to as “forward”. The direction opposite to the forward direction is referred to as “rearward”. A horizontal direction orthogonal to the front-back direction X is referred to as a “transverse direction Y”. One direction of the transverse direction Y is referred to as a “rightward direction” appropriately. The direction opposite to the rightward direction is referred to as “leftward”. The perpendicular direction relative to the horizontal direction is referred to as a “vertical direction Z”. For reference, FIG. 1 shows front, rear, right, left, up, and down, as appropriate, for example.

2. Stocker Block

The stocker block 3 accommodates at least one carrier C. One or more (e.g., two) load ports 9 are provided in the stocker block 3. The stocker block 3 includes a carrier transport mechanism (robot) 11 and shelves 13.

The carrier transport mechanism 11 transports the carrier C between the load port 9 and the shelf 13. The carrier transport mechanism 11 includes a gripper configured to grip a projected portion on an upper face of the carrier C, or a hand configured to support the carrier C while contacting a bottom face of the carrier C. The shelf 13 is classified into a shelf 13A for taking and housing the substrates W and a shelf 13B for storage.

The shelf 13A adjoins the transferring block 5. The shelf 13A may be provided with a mechanism for attaching and detaching a lid of the carrier C. At least one shelf 13A is provided. The shelf 13A places the carrier C thereon. The carrier C accommodates a plurality of (e.g., twenty-five) substrates W in a horizontal posture at a predetermined pitch (e.g., a pitch of 10 mm) in the vertical direction Z. Here, the substrates W are aligned in a thickness direction thereof. A front opening unify pod (FOUP) is used as the carrier C, for example. The FOUP is a sealing container. The carrier C may be an opened container, which type is not specified.

3. Transferring Block

The transferring block 5 adjoins rearward X of the stocker block 3. The transferring block 5 includes a substrate handling mechanism (robot) HTR and a first posture turning mechanism 15.

The substrate handling mechanism HTR is provided rightward Y in the transferring block 5. The substrate handling mechanism HTR can collectively transport a plurality of (e.g., twenty-five) substrates Win a horizontal posture among the carrier C placed on the shelf 13A, the first posture turning mechanism 15, and a buffer unit 27 (mentioned later).

Reference is made to FIG. 2. The substrate handling mechanism HTR includes a plurality of (e.g., twenty-five) hands 17. In FIG. 2, the substrate handling mechanism HTR includes three hands 17 for convenience of illustration. The hands 17 each hold one substrate W.

The substrate handling mechanism HTR further includes a hand supporting portion 19, an advancing and withdrawing portion 20, and a lifting and rotating portion 21. The hand supporting portion 19 supports a plurality of hands 17. Accordingly, the hands 17 are moved integrally. The advancing and withdrawing portion 20 causes the hands 17 to advance and withdraw via the hand supporting portion 19. The lifting and rotating portion 21 rotates the advancing and withdrawing portion 20 around a vertical axis AX1, thereby rotating the hands 17 and the like around the vertical axis AX1. Moreover, the lifting and rotating portion 21 moves the advancing and withdrawing portion 20 upward and downward, thereby moving the hands 17 and the like upward and downward. The lifting and rotating portion 21 is fixed on the floor. That is, the lifting and rotating portion 21 does not move in the horizontal direction. Here, the advancing and withdrawing portion 20 and the lifting and rotating portion 21 each include an electric motor. Here, the substrate handling mechanism HTR may include another hand, not shown, for transporting one substrate W in addition to the hands 17 and the hand supporting portion 19.

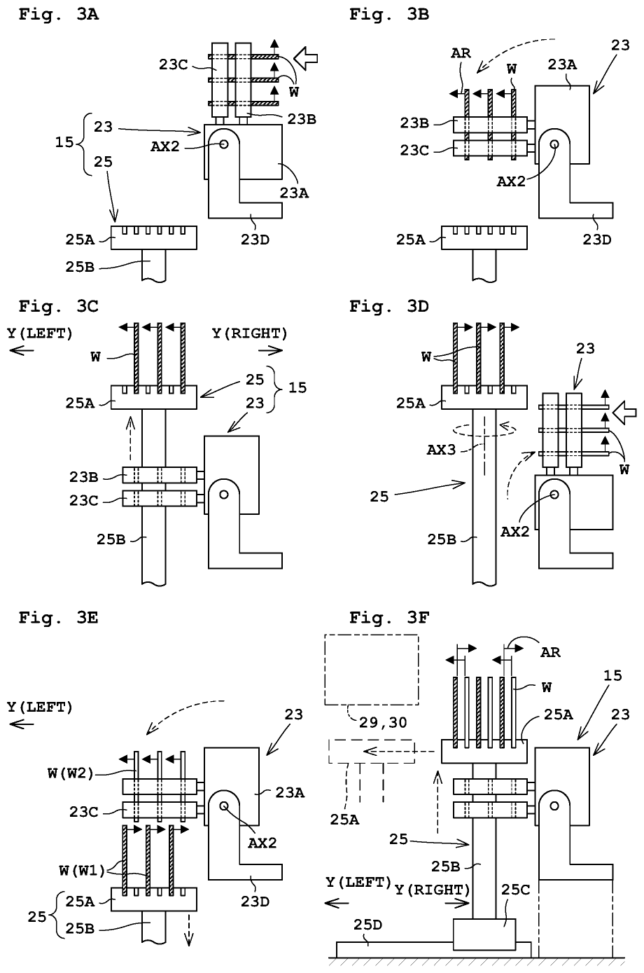

Reference is made to FIG. 1. The first posture turning mechanism 15 turns a posture of the substrates W, taken out of the carrier C, from horizontal to vertical. The first posture turning mechanism 15 includes a posture turning unit 23 and a pusher mechanism 25. In FIG. 1, the substrate handling mechanism HTR, the posture turning unit 23, and the pusher mechanism 25 are arranged leftward Y in this order. FIGS. 3A to 3F are each a side view illustrating the first posture turning mechanism 15 (posture turning unit 23 and pusher mechanism 25) in the transferring block 5.

As shown in FIGS. 1 and 3A, the posture turning unit 23 includes a support base 23A, one-paired horizontal holders 23B, one-paired vertical holders 23C, and a rotation driving portion 23D. The one-paired horizontal holders 23B and the one-paired vertical holders 23C are provided on the support base 23A. The horizontal holders 23B and the vertical holders 23C receive the substrates W transported by the substrate handling mechanism HTR. When the substrates W are in the horizontal posture, the one-paired horizontal holders 23B support the substrates W from below while contacting a lower face of each of the substrates W. In contrast to this, when the substrates W are in the vertical posture, the one-paired vertical holders 23C hold the substrates W.

The rotation driving portion 23D supports the support base 23A rotatably around a horizontal axis AX2. Moreover, the rotation driving portion 23D rotates the support base 23A around the horizontal axis AX2, whereby a posture of the substrates W held by the holders 23B and 23C is turned from horizontal to vertical.

As illustrated in FIGS. 1 and 3F, the pusher mechanism 25 includes a pusher 25A, a lifting and rotating portion 25B, a horizontally moving portion 25C, and a rail 25D. The pusher 25A supports each lower part of plurality of (e.g., fifty) substrates W in the vertical posture. Here in FIGS. 3A to 3F, the pusher 25A is configured so as to be able to support six substrates W for convenience of illustration.

The lifting and rotating portion 25B is connected to a lower face of the pusher 25A. The lifting and rotating portion 25B expands and contracts, thereby moving the pusher 25A in the up-down direction. Moreover, the lifting and rotating portion 25B rotates the pusher 25A around a vertical axis AX3. The horizontally moving portion 25C supports the lifting and rotating portion 25B. The horizontally moving portion 25C moves the pusher 25A and the lifting and rotating portion 25B horizontally along the rail 25D. The rail 25D is formed so as to extend in the transverse direction Y. The rotation driving portion 23D, the lifting and rotating portion 25B, and the horizontally moving portion 25C each include an electric motor.

Description is now made of operation of the first posture turning mechanism 15. Batch process tanks BT1 to BT6, mentioned later, in the treating block 7 each perform treatment on fifty substrates W in two carriers C, for example, collectively. The first posture turning mechanism 15 turns a posture of the fifty substrates W in a batch of twenty-five. Moreover, the first posture turning mechanism 15 arranges the substrates W at a predetermined pitch (e.g., a half pitch) in a face-to-face system. Here, a half pitch is a pitch of 5 mm, for example. The pusher mechanism 25 transports the fifty substrates W to the transport mechanism WTR.

Here, twenty-five substrates W in a first carrier C are to be described as substrates W1 in a first substrate group. Twenty-five substrates W in a second carrier C are to be described as substrates W2 in a second substrate group. Moreover, description is made in FIGS. 3A to 3F that the number of substrates W1 in the first substrate group is three, and the number of substrates W2 in the second substrate group is three for convenience of illustration. Moreover, when no particular distinction is made between the substrate W1 and the substrate W2, the substrate W1 and the substrate W2 are described as a “substrate W”.

Reference is made to FIG. 3A. The posture turning unit 23 receives twenty-five substrates W1 in a first substrate group, transported from the substrate handling mechanism HTR, with the holders 23B, 23C. At this time, the twenty-five substrates W1 are in a horizontal posture, and device faces thereof are directed upward. The twenty-five substrates W1 are arranged at a predetermined pitch (full pitch). Here, a full pitch is a pitch of 10 mm, for example. The full pitch is also called a normal pitch.

Here, a half pitch is half the full pitch. Moreover, the device face of the substrate W (W1, W2) is a face where electronic circuits are formed, and is called a “front face”. Moreover, a back face of the substrate W is a face where no electronic circuits are formed. A face opposite to the device face corresponds to the back face.

Reference is made to FIG. 3B. The posture turning unit 23 rotates the holders 23B, 23C by 90 degrees around the horizontal axis AX2 to turn a posture of the twenty-five substrates W1 from horizontal to vertical. Reference is made to FIG. 3C. The pusher mechanism 25 moves the pusher 25A upward to a position higher than the holders 23B, 23C of the posture turning unit 23. Accordingly, the pusher 25A receives the twenty-five substrates W1 from the holders 23B, 23C. The twenty-five substrates W1 held by the pusher 25A are directed leftward Y. Here in FIGS. 3A to 3F, a direction of the device face of the substrate W is denoted by an arrow AR.

Reference is made to FIG. 3D. The pusher mechanism 25 rotates the twenty-five substrates W1 in the vertical posture by 180 degrees around the vertical axis AX3. Accordingly, the twenty-five substrates W1 are reversed to be directed rightward Y. Moreover, the reversed twenty-five substrates W1 are moved leftward Y from a position before the reverse by a half pitch (e.g., 5 mm). Moreover, the holders 23B, 23C of the posture turning unit 23 are rotated by −90 degrees around the horizontal axis AX2 such that the holders 23B, 23C can receive next substrates W2. Thereafter, the posture turning unit 23 receives twenty-five substrates W2 in a second substrate group, transported by the substrate handling mechanism HTR, with the holders 23B, 23C. At this time, the twenty-five substrates W2 are in a horizontal posture, and device faces thereof are directed upward. Here, the posture turning unit 23 and the pusher mechanism 25 operate so as not to interfere with each other.

Reference is made to FIG. 3E. The pusher mechanism 25 moves the pusher 25A, holding the twenty-five substrates W1 in the first substrate group, downward to a retreating position. Thereafter, the posture turning unit 23 turns a posture of the twenty-five substrates W2 from horizontal to vertical. The twenty-five substrates W2 whose posture is turned are directed leftward Y. Reference is made to FIG. 3F. Thereafter, the pusher mechanism 25 moves the pusher 25A, holding the twenty-five substrates W2 in the second substrate group, upward. Accordingly, the pusher mechanism 25 also receives the twenty-five substrates W2 from the posture turning unit 23.

Accordingly, the pusher 25A holds fifty substrates W (W1, W2) in the first substrate group and the second substrate group. For the fifty substrates W, the twenty-five substrates W1 and the twenty-five substrates W2 are alternately arranged one by one. The fifty substrates W are arranged at a half pitch (e.g., 5 mm). Moreover, the twenty-five substrates W1 are directed in a reverse direction to the direction of the twenty-five substrates W2. Consequently, the fifty substrates W are arranged in a face-to-face system. That is, for adjacent two substrates W1, W2, two device faces thereof (or two back faces) face each other.

Thereafter, the pusher mechanism 25 moves the pusher 25A, holding the fifty substrates W, to a substrate delivery position PP below one-paired chucks 29, 30 of the transport mechanism WTR along the rail 25D.

4. Treating Block 7

The treating block 7 adjoins the transferring block 5. The treating block 7 is located rearward X of the transferring block 5. The treating block 7 includes a batch treatment region R1, a batch substrate transport region R2, a posture turning region R3, a single-wafer transportation region R4, and a single-wafer treatment region R5. Moreover, the substrate treating apparatus 1 includes a buffer unit 27 on which substrates W are placed.

4-1. Batch Treatment Region R1

The batch treatment region R1 adjoins the batch substrate transport region R2, the posture turning region R3, and the single-wafer treatment region R5. Moreover, the batch treatment region R1 extends in a direction apart from the transferring block 5 (rearward X).

The batch treatment region R1 contains six batch process tanks BT1 to BT6, for example. The six batch process tanks BT1 to BT6 are arranged in line in the front-back direction X where the batch treatment region R1 extends. Note that the number of batch process tanks is not limited to six, and the number only needs to be plural.

The six batch process tanks BT1 to BT6 each perform immersion treatment on a plurality of substrates W in the vertical posture collectively. For example, the six batch process tanks BT1 to BT6 is formed by four chemical liquid process tanks BT1 to BT4 and two water cleaning process tanks BT5 and BT6. Specifically, the two chemical liquid process tanks BT1 and BT2 and the water cleaning process tank BT5 are set as one set. Then, the two chemical liquid process tanks BT3 and BT4 and the water cleaning process tank BT6 are set as another set.

The four chemical liquid process tanks BT1 to BT4 each perform etching treatment with chemical. A phosphoric acid liquid is used as the chemical, for example. The chemical liquid process tank BT1 stores the chemical supplied from a chemical liquid jet pipe, not shown. The chemical liquid jet pipe is provided in an inner wall of the chemical liquid process tank BT1. The three chemical liquid process tanks BT2 to BT4 are each configured in the same manner as the chemical liquid process tank BT1.

The two water cleaning process tanks BT5 and BT6 each perform pure water cleaning treatment by cleaning off the chemical, adhered to the substrates W, with pure water. Deionized water (DIW) is, for example, used as pure water. The two water cleaning process tanks BT5 and BT6 each store pure water supplied from a cleaning liquid jet pipe, not shown. The cleaning liquid jet pipe is provided in inner walls of the water cleaning process tanks BT5 and BT6.

The six batch process tanks BT1 to BT6 contain six lifters LF1 to LF6, respectively. For example, the lifter LF1 holds the substrates W arranged at a predetermined pitch (half pitch) in the vertical posture. Moreover, the lifter LF1 moves the substrates W upward and downward between a treating position inside of the batch process tank (chemical liquid process tank) BT1 and a delivery position above the batch process tank BT1. The other five lifters LF2 to LF6 are configured in the same manner as the lifter LF1.

4-2. Batch Substrate Transport Region R2

The batch substrate transport region R2 adjoins the transferring block 5, the batch treatment region R1, and the posture turning region R3. The batch substrate transport region R2 is provided along the batch treatment region R1. The batch substrate transport region R2 has a first end side extending to the transferring block 5, and a second end side extending in a direction (rearward X) so as to be apart from the transferring block 5. The batch substrate transport region R2 extends parallel to the batch treatment region R1.

The batch substrate transport region R2 has a transport mechanism (robot) WTR. That is, the batch substrate transport region R2 is provided with the transport mechanism WTR. The transport mechanism WTR transports a plurality of (e.g., fifty) substrates W in a vertical posture collectively among the substrate delivery position PP defined in the transferring block 5, the six batch process tanks BT1 to BT6, for example, and a second posture turning mechanism 35 (lifter LF9). When the transport mechanism WTR passes the second posture turning mechanism 35, the transport mechanism WTR moves above a horizontally moving portion 95 of a posture turning unit 63 mentioned later.

The transport mechanism WTR includes one-paired chucks 29, 30, and a guide rail 33. The one-paired chucks 29, 30 each have fifty holding grooves for holding the fifty substrates W individually, for example. The two chucks 29, 30 extend in parallel in the Y-direction in plan view (FIG. 1). The transport mechanism WTR opens and closes the two chucks 29, 30. The transport mechanism WTR moves the one-paired chucks 29, 30, along the guide rail 33. The transport mechanism WTR is driven by an electric motor. Here, the transport mechanism WTR corresponds to the batch substrate transport mechanism in the present invention.

4-3. Posture Turning Region R3

The posture turning region R3 is provided between the transferring block 5 and the batch treatment region R1. Moreover, the posture turning region R3 is provided among the batch substrate transport region R2, the single-wafer transportation region R4, and the single-wafer treatment region R5. Accordingly, the posture turning region R3 adjoins the transferring block 5, the batch treatment region R1, the batch substrate transport region R2, the single-wafer transportation region R4, and the single-wafer treatment region R5.

The posture turning region R3 contains the second posture turning mechanism 35. The second posture turning mechanism 35 turns a posture of the substrates W, on which batch treatment is performed, from vertical to horizontal. Detailed description is made later of the second posture turning mechanism 35. Here, the second posture turning mechanism 35 corresponds to the posture turning mechanism in the present invention.

4-4. Single-Wafer Transportation Region R4

The single-wafer transportation region R4 adjoins the transferring block 5, the posture turning region R3, and the single-wafer treatment region R5. Moreover, the single-wafer transportation region R4 is provided so as to face the batch substrate transport region R2 across the posture turning region R3.

The single-wafer transportation region R4 contains a center robot CR. The center robot CR can transport the substrates W in a horizontal posture one by one among the second posture turning mechanism 35, single-wafer processing chambers SW1, SW2, mentioned later, and the buffer unit 27. Moreover, around the center robot CR, the transferring block 5, the second posture turning mechanism 35, and the single-wafer processing chambers SW1, SW2 can be arranged. This can shorten a transportation distance of the substrates W by the center robot CR, resulting in effective transportation of the substrates W. Here, the center robot CR corresponds to the horizontal substrate transport mechanism in the present invention.

The center robot CR includes two hands 37A, 37B, two articulated arms 39A, 39B, and a lifting and lowering board 41. The two hands 37A, 37B each hold one substrate W in a horizontal posture. The two hands 37A, 37B are each movable horizontally. The two articulated arms 39A, 39B are each of a scalar type, for example. A distal end of the articulated arm 39A supports the hand 37A, and a distal end of the articulated arm 39B supports the hand 37B. The articulated arm 39A causes the hand 37A to move in a horizontal direction (front-back direction X and transverse direction Y), and the articulated arm 39B causes the hand 37B to move in the horizontal direction. The lifting and lowering board 41 supports proximal ends of the two articulated arms 39A and 39B. The lifting and lowering board 41 is configured so as to be extendible and contractible in an up-down direction. Accordingly, the lifting and lowering board 41 moves the two hands 37A, 37B and the two articulated arms 39A, 39B upward and downward. A position of the lifting and lowering board 41 in the horizontal direction is fixed without being moved. This can shorten a transportation distance of the substrates W by which the lifting and lowering board 41 moves in the horizontal direction, for example. In addition, movement of the lifting and lowering board 41 can be omitted.

The buffer unit 27 is arranged across the transferring block 5 and the single-wafer transportation region R4. That is, the buffer unit 27 is provided on a boundary between the transferring block 5 and the single-wafer transportation region R4. Moreover, the buffer unit 27 may be provided in either the transferring block 5 or the single-wafer transportation region R4 only. Accordingly, the buffer unit 27 may be provided fixedly in any of, the transferring block 5, the single-wafer transportation region R4, or the boundary between the transferring block 5 and the single-wafer transportation region R4. Here, the center robot CR includes the two hands 37A, 37B and the two articulated arms 39A, 39B, respectively. Alternatively, the center robot CR may include one pair or three or more pairs of the hands and the articulated arms.

The buffer unit 27 includes a plurality of mount shelves. The mount shelves are in a horizontal posture. Each of the mount shelves is capable of placing one substrate W. The buffer unit 27 places the substrates W in the horizontal posture at a predetermined pitch (full pitch) in the vertical direction Z. That is, the mount shelves are arranged at a predetermined pitch (full pitch) in the vertical direction Z. The buffer unit 27 is configured so as to place at least twenty-five substrates W, for example, that the substrate handling mechanism HTR can transport. The buffer unit 27 is configured to be capable of placing fifty substrates W, for example. The number of mount shelves in the buffer unit 27 may be two or more and twenty-four or less as necessary.

4-5. Single-Wafer Treatment Region R5

The single-wafer treatment region R5 adjoins the batch treatment region R1, the posture turning region R3, and the single-wafer transportation region R4. The single-wafer treatment region R5 is provided so as to face transferring block 5 across the single-wafer transportation region R4.

A plurality of (e.g., two) single-wafer processing chambers SW1, SW2 are provided in the single-wafer treatment region R5. The two single-wafer processing chambers SW1, SW2 are arranged in the transverse direction Y orthogonal to the front-back direction X where the batch treatment region R1 extends. The single-wafer processing chambers SW1, SW2 are each configured to perform treatment on the substrates W in a horizontal posture one by one. The first single-wafer processing chamber SW1 is located rightward Y of the posture turning region R3. The second single-wafer processing chamber SW2 is located rightward Y of the first single-wafer processing chamber SW1.

Moreover, the single-wafer processing chambers SW1, SW2 may be formed in plural steps. For example, six single-wafer processing chambers SW1, SW2 may be arranged as two in the transverse direction Y (horizontal direction) by three in the vertical direction Z. Note that the number of single-wafer processing chambers is not limited to two or six.

For example, the first single-wafer processing chamber SW1 includes a rotating unit 45 and a nozzle 47. The rotating unit 45 includes a spin chuck configured to hold one substrate W in a horizontal posture, and an electric motor configured to rotate the spin chuck around a vertical axis passing through the center of the substrate W. The spin chuck may hold a lower face of the substrate W by vacuum adsorption. Moreover, the spin chuck may include three or more chuck pins for gripping an outer edge of the substrate W.

The nozzle 47 supplies a treatment liquid to the substrate W held by the rotating unit 45. The nozzle 47 moves between a stand-by position apart from the rotating unit and a supply position above the rotating unit 45. Deionized water (DIW) or Isopropyl alcohol (IPA) is used, for example, as the treatment liquid. The single-wafer processing chamber SW1 may perform cleaning treatment on the substrates W with deionized water, and then may form an IPA liquid film on top faces of the substrates W, for example.

The single-wafer processing chamber SW2 performs dry treatment with supercritical fluid, for example. A carbon dioxide liquid is used as the fluid, for example. The single-wafer processing chamber SW2 includes a chamber body (vessel) 48, a supporting tray, and a lid. The chamber body 48 includes a treating space provided therein, an opening through which the substrates W enter the treating space, a supply port, and an exhaust port. The substrates W are accommodated into the treating space while being supported by the supporting tray. The lid closes the opening of the chamber body 48. For example, the single-wafer processing chamber SW2 makes the fluid into a supercritical state and supplies the supercritical fluid from the supply port into the treating space of the chamber body 48. At this time, gas within the treating space of the chamber body 48 is exhausted from the exhaust port. With the supercritical fluid supplied into the treating space, dry treatment is performed on the substrates W.

The supercritical state is obtained by bringing fluid into critical temperature and pressure inherent in the fluid. Specifically, when the fluid is carbon dioxide, a critical temperature is 31 degrees Celsius and critical pressure is 7.38 MPa. The dry treatment is performed on the substrates W with the supercritical fluid, leading to suppressed collapse of patterns formed on the substrates W.

5. Controller

The substrate treating apparatus 1 includes the controller 59 and a memory unit (not shown). The controller 59 controls components of the substrate treating apparatus 1. The controller 59 includes one or more processors like a central processing unit (CPU). The memory unit includes, for example, at least one of a read-only memory (ROM), a random-access memory (RAM), and a hard disk. The memory unit stores computer programs necessary for controlling each component of the substrate treating apparatus 1.

6. Second Posture Turning Mechanism

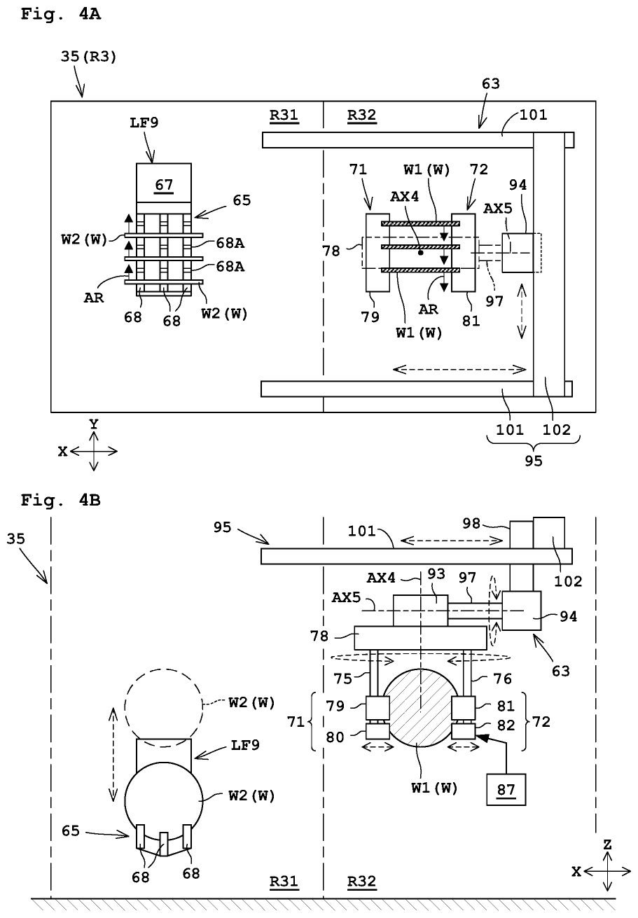

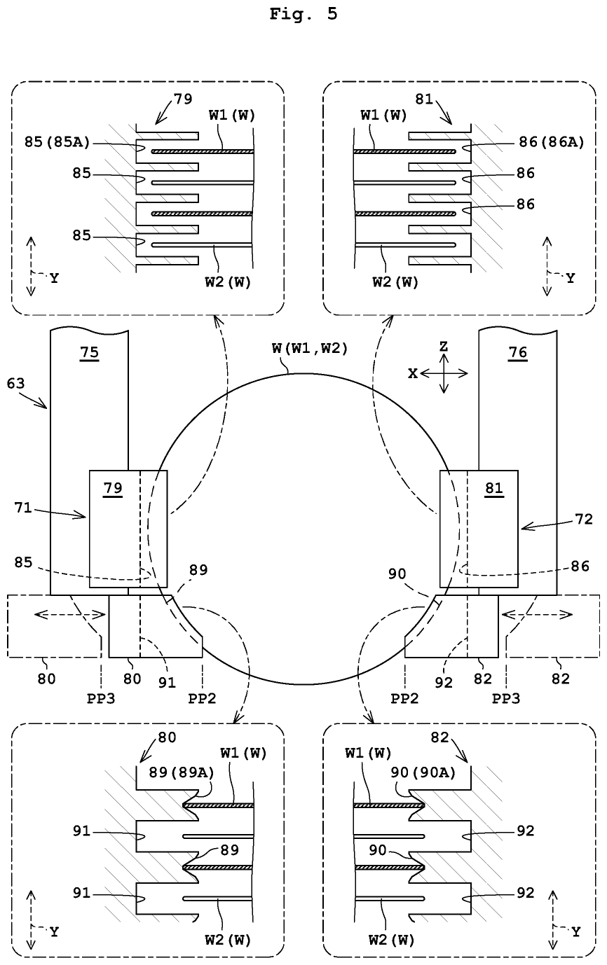

FIG. 4A is a plan view of the second posture turning mechanism 35. FIG. 4B is a front view of the second posture turning mechanism 35. FIG. 5 is a front view illustrating two chucks 71, 72 of the posture turning unit 63 (horizontal holders 79, 81 and vertical holders 80, 82).

The second posture turning mechanism 35 includes a substrate stand-by region R31 and a substrate posture turning region R32. The substrate stand-by region R31 and the substrate posture turning region R32 are arranged in the front-back direction X where the batch treatment region R1 or the six batch process tanks BT1 to BT6 extend.

The second posture turning mechanism 35 includes a lifter LF9 and a posture turning unit 63. The lifter LF9 is provided in the substrate stand-by region R31. In contrast to this, the posture turning unit 63 is provided in the substrate posture turning region R32. The following describes the lifter LF9 and the posture turning unit 63 in detail.

6-1. Lifter LF9

The lifter LF9 holds a plurality of (e.g., fifty) substrates W, transported by the transport mechanism WTR, in a vertical posture. The lifter LF9 includes a substrate holder 65, and a lifting member 67 for moving the substrate holder 65 upward and downward in the vertical direction Z. The substrate holder 65 corresponds to the substrate holder in the present invention.

The substrate holder 65 holds fifty substrates W, for example, arranged at a predetermined pitch (half pitch) from the below. The substrate holder 65 includes three holders 68, for example, that extend in the Y-direction. The three holders 68 each include holding grooves 68A whose number is same as the number of substrates W (e.g., fifty) for holding the fifty substrates W. The holding grooves 68A each have a recess formed in a V-shape. The lifting member 67 moves the substrate holder 65 upward and downward. The lifting member 67 includes an electric motor or an air cylinder, for example.

Here, the lifter LF9 (substrate holder 65) and the six batch process tanks BT1 to BT6 are arranged linearly in the front-back direction X such that the transport mechanism WTR can transport the fifty substrates W linearly.

6-2. Posture Turning Unit

The posture turning unit 63 receives the substrates W from the substrate holder 65, and turns a posture of the substrates W from vertical to horizontal. The posture turning unit 63 includes two chucks 71, 72, two arms 75, 76, and an arm supporting portion 78. The arm supporting portion 78 corresponds to the supporting portion in the present invention.

The posture turning unit 63 receives a plurality of (e.g., twenty-five) substrates W from the substrate holder 65 with the two chucks 71, 72 in the substrate stand-by region R31, and turns a posture of the substrates W from vertical to horizontal with a longitudinal rotator 94 in the substrate posture turning region R32. Detailed description is as under.

The two chucks 71, 72 hold a plurality of (e.g., twenty-five) substrates W. The first chuck 71 includes a first horizontal holder 79 and a first vertical holder 80. Moreover, the second chuck 72 includes a second horizontal holder 81 and a second vertical holder 82. The two horizontal holders 79, 81 and the two vertical holders 80, 82 are formed so as to extend in an alignment direction of the substrates W.

The two horizontal holders 79, 81 house two sides of each of the substrates W opposite to each other in a radial direction. The two horizontal holders 79, 81 place the substrates W in the horizontal posture at a predetermined pitch (e.g., half pitch). The two vertical holders 80, 82 house two sides of each of the substrates W. When the substrates W are in the vertical posture, the two vertical holders 80, 82 are provided below the horizontal holders 79, 81. Moreover, when the substrates W are in the vertical posture, the two vertical holders 80, 82 hold the substrates W in the vertical posture. Here, when the substrates W held by the two vertical holders 80, 82 are in the vertical posture, the two horizontal holders 79, 81 are arranged in the horizontal direction XY while the substrates W are interposed between the two horizontal holders 79, 81. Likewise, when the substrates W are in the vertical posture, the two vertical holders 80, 82 are arranged in the horizontal direction XY while the substrates W are interposed between the two horizontal holders 79, 81.

Reference is made to FIG. 5. The two horizontal holders 79, 81 includes plural-paired (e.g., fifty-paired) horizontal guide grooves 85, 86, respectively. Fifty first horizontal guide grooves 85 are provided in the horizontal holder 79. Fifty second horizontal guide grooves 86 are provided in the horizontal holder 81. For example, two horizontal guide grooves 85A, 86A face each other. When the substrates W are in the vertical posture, the plural-paired horizontal guide grooves 85, 86 have the same function as that of passing grooves 91, 92, respectively, mentioned later.

Moreover, the two horizontal holders 79, 81 may include twenty-five-paired horizontal guide grooves 85, 86, respectively, for example. Here, the number of pairs of the horizontal guide grooves 85, 86 is not limited to fifty or twenty-five. Also, the number of pairs of the holding grooves 89, 90 or the passing grooves 91, 92 is not limited to twenty-five.

The two vertical holders 80, 82 include plural-paired (e.g., twenty-five-paired) holding grooves 89, 90 and plural-paired (e.g., twenty-five-paired) passing grooves 91, 92, respectively. The plural-paired holding grooves 89, 90 each hold one substrate W. The passing grooves 91, 92 each passes one substrate W. The plural-paired passing grooves 91, 92 and the plural-paired holding grooves 89, 90 are alternately arranged one by one. Here, the two holding grooves 89A, 90A are arranged to face each other.

Twenty-five holding grooves 89 and twenty-five passing grooves 91 are provided in the first vertical holder 80. Twenty-five holding grooves 89 and twenty-five passing grooves 91 are arranged alternately one by one. Twenty-five holding grooves 90 and twenty-five passing grooves 92 are provided in the second vertical holder 82. Twenty-five holding grooves 90 and twenty-five passing grooves 92 are arranged alternately one by one. The holding grooves 89, 90 each have a recess formed in a V-shape. Accordingly, the holding grooves 89, 90 each can hold one substrate W in a horizontal posture. This can suppress falling down of the substrate W to an adjacent substrate W.

As shown in FIG. 4B, the first arm 75 supports the first horizontal holder 79 and the first vertical holder 80. The second arm 76 supports the second horizontal holder 81 and the second vertical holder 82. The arm supporting portion 78 supports upper ends (proximal ends) of the two arms 75, 76. The arm supporting portion 78 and the two arms 75, 76 are each formed in a C-shape or a U-shape.

The arm supporting portion 78 is arranged opposite to the two vertical holders 80, 82 across the two horizontal holders 79, 81. Accordingly, the arm supporting portion 78 and the like support the two horizontal holders 79, 81 and the two vertical holders 80, 82 via the two horizontal holders 79, 81 from a side opposite to the two vertical holders 80, 82.

Moreover, as shown in FIG. 5 by solid lines and alternate long and short dashed lines, the two vertical holders 80, 82 are configured to open and close horizontally. That is, the posture turning unit 63 includes an opening and closing portion 87 (see FIG. 4). The opening and closing portion 87 includes an electric motor or an air cylinder, for example. The opening and closing portion 87 moves the two vertical holders 80, 82 linearly between a holding position PP2 where a gap between the two vertical holders 80, 82 are narrowed for holding the substrates W with the two vertical holders 80, 82 and a passing position PP3 where the gap between the two vertical holders 80, 82 are widened for passing the substrates W through the two vertical holders 80, 82.

When the two vertical holders 80, 82 are at the holding position PP2, they are closed. For example, when the substrates W are in the vertical posture, a gap between the two vertical holders 80, 82 are narrowed. The two vertical holders 80, 82 are moved to the holding position PP2 by the opening and closing portion 87, whereby the two vertical holders 80, 82 hold the substrates W in the vertical posture held by the substrate holder 65, whereas the two horizontal holders 79, 81 house the substrates W held by the two vertical holders 80, 82. Moreover, when the two vertical holders 80, 82 are at the passing position PP3, they are opened. For example, when the longitudinal rotator 94 mentioned later rotates to turn the posture of the substrates W from vertical to horizontal, the opening and closing portion 87 moves the two vertical holders 80, 82 to the passing position PP3. That is, when the substrates W are in the horizontal posture, a gap between the two vertical holders 80, 82 are widened.

Moreover, the posture turning unit 63 includes a lateral rotator 93, the longitudinal rotator 94, the horizontally moving portion 95, a rotation shaft 97, and a vertical arm 98. The lateral rotator 93 supports the arm supporting portion 78 rotatably. The lateral rotator 93 rotates the two chucks 71, 72, the arm supporting portion 78 and the like around a rotary axis (vertical axis) AX4, orthogonal to an alignment direction of the substrates W, when the two vertical holders 80, 82 hold the substrates W in the vertical posture. The lateral rotator 93 and the longitudinal rotator 94 each include an electric motor, for example.

The rotation shaft 97 has a distal end connected to the lateral rotator 93. The rotation shaft 97 has a proximal end rotatably connected to the longitudinal rotator 94. The rotation shaft 97 extends in the horizontal direction (front-back direction X). Accordingly, a central axis of the rotation shaft 97 corresponds to a horizontal axis AX5. The horizontal axis (central axis) AX5 is positioned higher than the substrates W in the vertical posture held by the two vertical holders 80, 82. In order to turn the posture of the substrates W from vertical to horizontal, the longitudinal rotator 94 rotates the two chucks 71, 72, the arm supporting portion 78 and the like around the horizontal axis AX5. The longitudinal rotator 94 is supported at a lower end of the vertical arm 98.

The horizontally moving portion 95 moves the two chucks 71, 72, the arm supporting portion 78, the opening and closing portion 87, the lateral rotator 93, and the longitudinal rotator 94 horizontally. Moreover, the horizontally moving portion 95 moves the arm supporting portion 78 and the longitudinal rotator 94 horizontally between the substrate stand-by region R31 where the substrate holder 65 is arranged and the substrate posture turning region R32 for turning a posture of the substrates W from vertical to horizontal.

The horizontally moving portion 95 is positioned higher than the substrates W in the vertical posture held by the two vertical holders 80, 82. Accordingly, the two chucks 71, 72 are suspended. This prevents contamination of the moving unit and the rotating portion due to falling of droplets adhered to the substrates W. Consequently, failure of the moving unit and the rotating portion due to contamination with droplets can be prevented.

The horizontally moving portion 95 includes an X-direction moving portion 101 and a Y-direction moving portion 102. The X-direction moving portion 101 moves the two chucks 71, 72, the arm supporting portion 78 and the like in the front-back direction X. The Y-direction moving portion 102 moves the two chucks 71, 72, the arm supporting portion 78 and the like in the transverse direction Y. The two moving portions 101, 102 each include a linear actuator having an electric motor. In FIG. 4A, an upper end of the vertical arm 98 is movably connected to the Y-direction moving portion 102. The Y-direction moving portion 102 moves the vertical arm 98 in the transverse direction Y. Here, the horizontally moving portion 95 corresponds to the moving unit in the present invention.

7. Operation Explanation

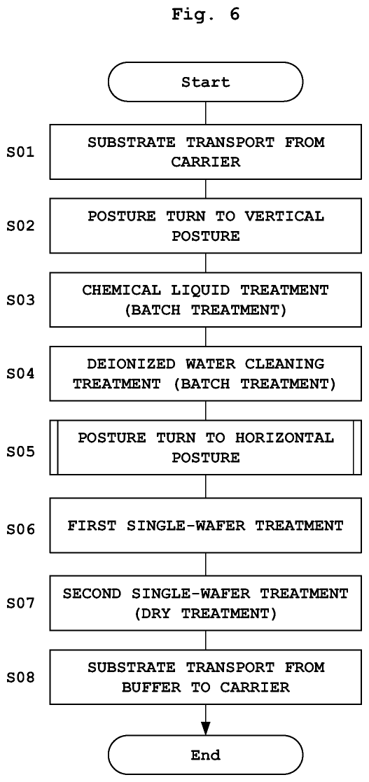

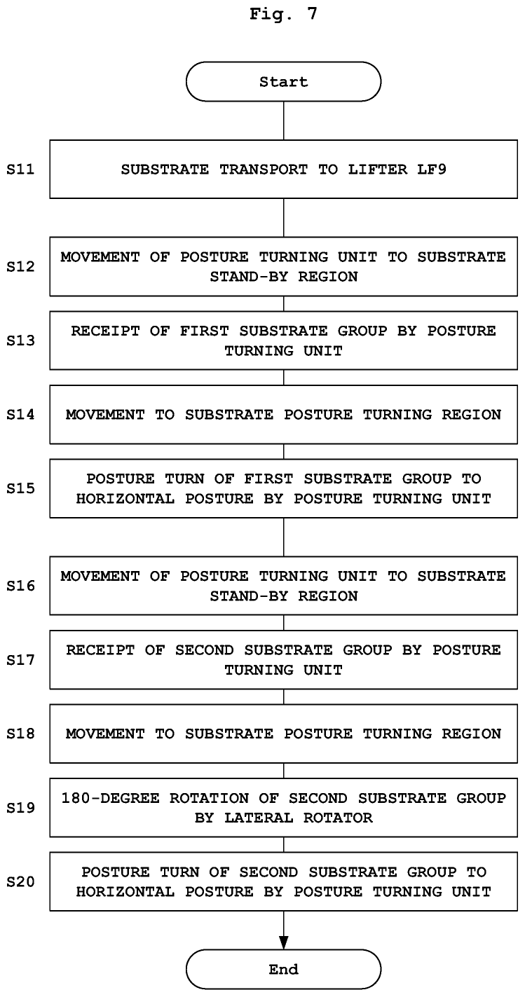

The following describes operation of the substrate treating apparatus 1 with reference to flowcharts in FIGS. 6 and 7. Reference is made to FIG. 1. An external transport robot, not shown, transports two carriers C into the load port 9 in order.

[Step S01] Transportation of Substrate from Carrier

The carrier transport mechanism 11 of the stocker block 3 transports a first carrier C from the load port 9 to a shelf 13A. The substrate handling mechanism HTR of the transferring block 5 takes twenty-five substrates W1 in a horizontal posture from the first carrier C placed on the shelf 13A, and transports the substrates W1 to the posture turning unit 23. Thereafter, the carrier transport mechanism 11 transports the empty first carrier C to another shelf 13B. Then, the carrier transport mechanism 11 transports a second carrier C from the load port 9 to the shelf 13A. The substrate handling mechanism HTR takes twenty-five substrates W2 in a horizontal posture from the second carrier C placed on the shelf 13A, and transports the substrates W1 to the posture turning unit 23.

[Step S02] Posture Turn to Vertical Posture

In the posture turning unit 23, fifty substrates W (W1, W2) of two carriers C are transported. As shown in FIGS. 3A to 3F, the posture turning unit 23 and the pusher mechanism 25 cause the fifty substrates W to be aligned at a half pitch (5 mm) in a face-to-face system, and turn the posture of the fifty substrates W from horizontal to vertical. The pusher mechanism 25 transports the fifty substrates W in the vertical posture to the substrate delivery position PP determined in the transferring block 5.

[Step S03] Chemical Treatment (Batch Treatment)

The transport mechanism WTR receives the fifty substrates W in the vertical posture from the pusher mechanism 25 at the substrate delivery position PP, and transports the fifty substrates W to any of the four lifters LF1 to LF4 in the four chemical liquid process tanks BT1 to BT4, respectively. Here, when the transport mechanism WTR passes the posture turning region R3, the transport mechanism WTR moves above the second posture turning mechanism 35, for example, so as not to interfere with the second posture turning mechanism 35.

For example, the transport mechanism WTR transports the fifty substrates W to the lifter LF1 of the chemical liquid process tank BT1. The lifter LF1 receives the fifty substrates W at a position above the chemical liquid process tank BT1. The lifter LF1 immerses the fifty substrates W in phosphoric acid as the treatment liquid within the chemical liquid process tank BT1. Accordingly, an etching treatment is performed on the fifty substrates W. After the etching treatment, the lifter LF1 pulls up the fifty substrates W from the phosphoric acid within the chemical liquid process tank BT1. It should be noted that similar treatment as in the chemical liquid process tank BT1 is performed when the fifty substrates W are transported to the other lifters LF2 to LF4 of the chemical liquid process tanks BT2 to BT4, respectively.

[Step S04] Deionized Water Cleaning Treatment (Batch Treatment)

The transport mechanism WTR receives the fifty substrates W in the vertical posture from the lifter LF1 (or lifter LF2), for example, and transports the fifty substrates W to the lifter LF5 of the water cleaning process tank BT5. The lifter LF5 receives the fifty substrates W at a position above the water cleaning process tank BT5. The lifter LF5 immerses the fifty substrates W in the deionized water within the water cleaning process tank BT5. Accordingly, a cleaning treatment is performed on the fifty substrates W.

Here, when the transport mechanism WTR receives the fifty substrates Win the vertical posture from either the lifter LF3 or LF4, the transport mechanism WTR transports the fifty substrates W to the lifter LF6 of the water cleaning process tank BT6. The lifter LF6 receives the fifty substrates W at a position above the water cleaning process tank BT6. The lifter LF6 immerses the fifty substrates W in the deionized water within the water cleaning process tank BT6.

[Step S05] Posture Turn to Vertical Posture

The second posture turning mechanism 35 turns a posture of the substrates W, on which the cleaning treatment is performed, from vertical to horizontal. Here, the following drawbacks arise. That is, if the posture of the fifty substrates W arranged at a half pitch (a pitch of 5 mm) is collectively turned, the hands 37A, 37B of the center robot CR may not possibly enter a gap between two adjacent substrates W of the fifty substrates W satisfactorily.

In addition, when the substrates W are aligned in a face-to-face system, the substrates W whose posture is turned to horizontal may be a substrate W whose device face is directed upward or be a substrate W whose device face is directed downward. For example, it is not suitable that the hands 37A, 37B of the center robot CR contact the device face of the substrate W. It is also not suitable that substrates W whose directions of the device faces are different are transported to the single-wafer processing chambers SW1, SW2.

Then, in this embodiment, a gap between two adjacent substrates W is widened and the device faces of the fifty substrates W face in the same direction. Detailed description is made with reference to the flowchart in FIG. 7 and FIGS. 1, 8A to 11C.

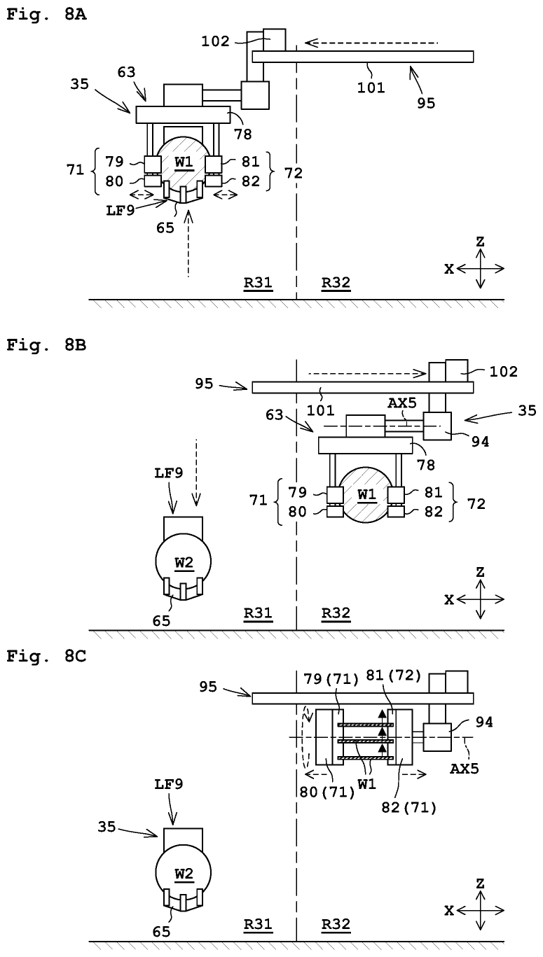

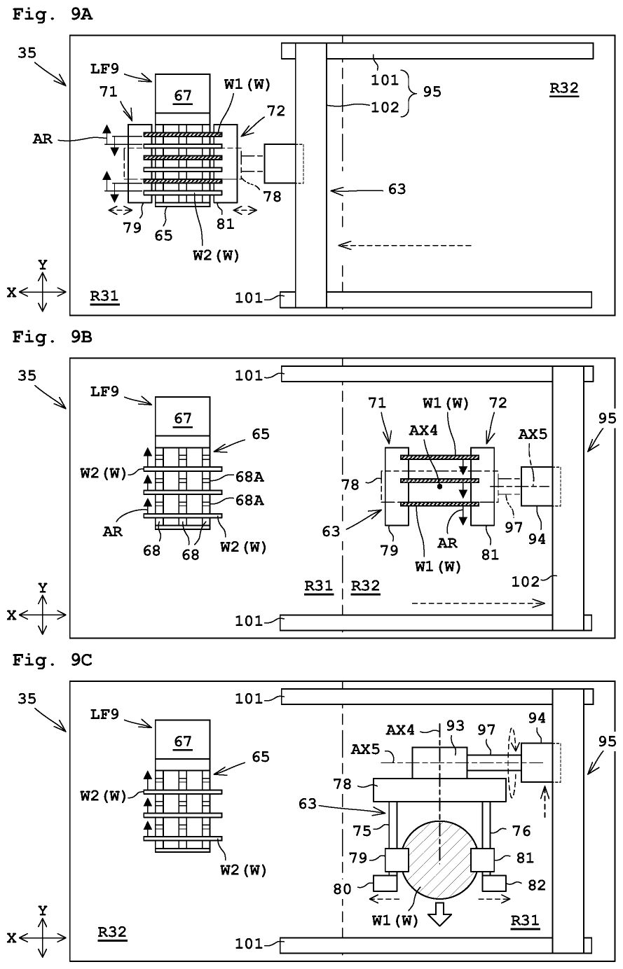

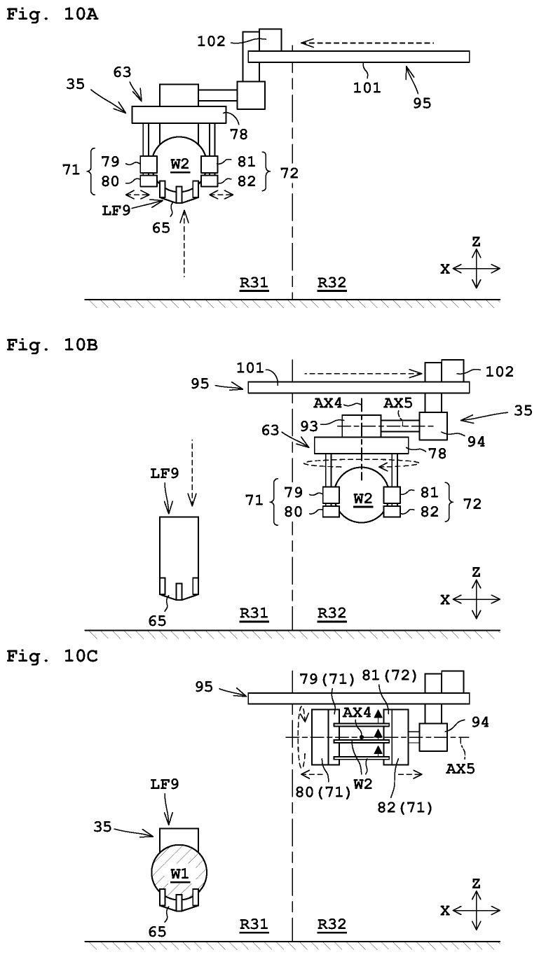

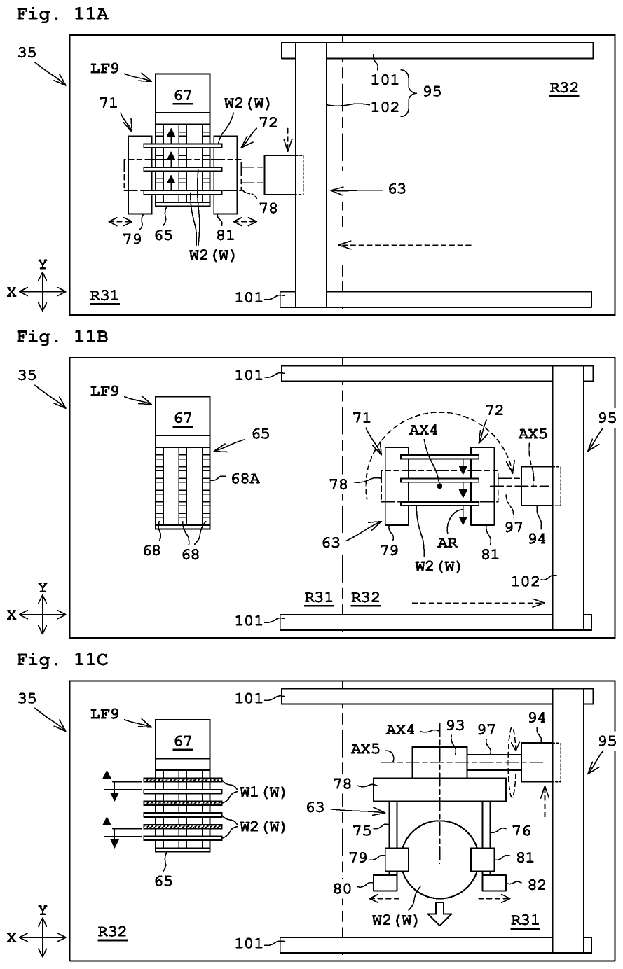

Now, FIGS. 8A to 8C and FIGS. 10A to 10C are each a front view of the second posture turning mechanism 35. FIGS. 9A to 9C and FIGS. 11A to 11C are each a plan view of the second posture turning mechanism 35. For example, FIG. 9A has correspondence to FIG. 8A. Moreover, FIG. 11B has correspondence to FIG. 10B.

[Step S11] Transport of Substrate to Lifter LF9

Reference is made to FIG. 1. The transport mechanism WTR transports the fifty substrates W from either the lifter LF5 or LF6 to the substrate holder 65 of the lifter LF9 of the second posture turning mechanism 35. The substrate holder 65 of the lifter LF9 holds the fifty substrates W in the vertical posture arranged in a face-to-face system and at a half pitch collectively. Moreover, the fifty substrates W are aligned in the transverse direction Y.

[Step S12] Movement of Posture Turning Unit to Substrate Stand-by Region

Reference is made to FIGS. 8A and 9A. When the fifty substrates W in the vertical posture are held by the substrate holder 65, the horizontally moving portion 95 of the posture turning unit 63 (mainly, X-direction moving portion 101) moves the two chucks 71, 72, the arm supporting portion 78 and the like from the substrate posture turning region R32 to the above of the substrate holder 65 of the substrate stand-by region R31. Moreover, the Y-direction moving portion 102 of the horizontally moving portion 95 moves the two chucks 71, 72, the arm supporting portion 78 and the like to the first substrate holding position. Here, the first substrate holding position is a position where twenty-five-paired holding grooves 89, 90 can hold twenty-five substrates W1 in a first substrate group.

Moreover, the opening and closing portion 87 of the posture turning unit 63 moves the two vertical holders 80, 82 horizontally in a direction where the holders are apart from each other to be opened (see passing position PP3 in FIG. 5).

[Step S13] Receipt of First Substrate Group by Posture Turning Unit

The two vertical holders 80, 82 are moved to the holding position PP2 by the opening and closing portion 87, whereby the two vertical holders 80, 82 hold a first divided substrate group (twenty-five substrates W1), made by taking every other substrate out of the fifty substrates W in a vertical posture held by the substrate holder 65, with the twenty-five-paired holding grooves 89, 90, whereas the two horizontal holders 79, 81 house the first divided substrate group (twenty-five substrates W1). Detailed description is as under.

The substrate holder 65 holds fifty substrates W (W1, W2) in the vertical posture. The lifting member 67 of the lifter LF9 moves the substrate holder 65 upward to an upper position where the substrates W can be delivered. At this time, the fifty substrates W pass through a gap between the two vertical holders 80, 82, and are inserted into fifty-paired horizontal guide grooves 85, 86 of the two horizontal holders 79, 81 individually.

Then, the opening and closing portion 87 moves the two vertical holders 80, 82 horizontally in a direction where the holders are closer to each other to be closed (see holding position PP2 in FIG. 5). Accordingly, the fifty substrates W held by the substrate holder 65 in the vertical posture are housed with the twenty-five-paired holding grooves 89, 90 and the twenty-five-paired passing grooves 91, 92 arranged alternately in pairs, which is as shown in two lower frames in FIG. 5.

Thereafter, the lifting member 67 of the lifter LF9 moves the substrate holder 65 downward to a lower stand-by position. Accordingly, the twenty-five substrates W1 in the first substrate group is delivered to the posture turning unit 63, whereas the twenty-five substrates W2 in a second substrate group remain in the substrate holder 65. That is, the posture turning unit 63 takes out the twenty-five substrates W1 in the first substrate group of the fifty substrates W, from the substrate holder 65 while holding the substrates W1 with the holding grooves 89, 90. Here, the substrates W1 in the first substrate group correspond to the first divided substrate group in the present invention. Moreover, the substrates W2 in the second substrate group corresponds to the second divided substrate group in the present invention.

The twenty-five substrates W1 taken out alternately are aligned at a full pitch. The residual twenty-five substrates W2 in the substrate holder 65 are also arranged at a full pitch. The residual twenty-five substrates W2 in the substrate holder 65 are at a stand-by state.

[Step S14] Movement to Substrate Posture Turning Region

Reference is made to FIGS. 8B and 9B. The horizontally moving portion 95 (X-direction moving portion 101 and Y-direction moving portion 102) moves the two chucks 71, 72, the arm supporting portion 78 and the like from the above of the substrate holder 65 in the substrate stand-by region R31 to a predetermined position in the substrate posture turning region R32 while holding the twenty-five substrates W1 with the two vertical holders 80, 82. That is, the posture turning unit 63 transports the twenty-five substrates W1 in the first substrate group in the vertical posture to the substrate posture turning region R32.

[Step S15] Horizontal Posture Turn of First Substrate Group by Posture Turning Unit

Reference is made to FIGS. 8C and 9C. Thereafter, the posture turning unit 63 turns a posture of the taken-out twenty-five substrates W1 to horizontal in the substrate posture turning region R32. Specifically, the longitudinal rotator 94 of the posture turning unit 63 rotates the substrates W1, the two chucks 71, 72, the arm supporting portion 78 by 90 degrees around the horizontal axis AX5 such that the two vertical holders 80, 82 face the center robot CR (see FIG. 1).

In such a condition, the center robot CR cannot take the substrates W1 out of the posture turning unit 63. Accordingly, the opening and closing portion 87 of the posture turning unit 63 moves the two vertical holders 80, 82 horizontally in a direction where the holders are apart from each other to be opened. That is, the opening and closing portion 87 moves the two vertical holders 80, 82 into the passing position PP3 when twenty-five substrates W1 whose posture is turned to horizontal are placed on the two horizontal holders 79, 81. This can pass the substrates W1 between the two vertical holders 80, 82. Moreover, the twenty-five substrates W1 are placed on the twenty-five horizontal guide grooves 85, 86 individually. The twenty-five substrates W1 are aligned at a full pitch, and thus the center robot CR can take out the substrates W easily.

Then, the center robot CR takes the twenty-five substrates W1 in the horizontal posture one by one with the two hands 37A, 37B while the substrates W1 pass between the two vertical holders 80, 82 moved into the passing position PP3, and transports the taken substrates W1 to the single-wafer processing chamber SW1.

[Step S16] Movement of Posture Turning Unit to Substrate Stand-by Region

Reference is made to FIGS. 10A and 11A. After the twenty-five substrates W1 are all transported from the posture turning unit 63, the horizontally moving portion 95 (mainly, X-direction moving portion 101) moves the two chucks 71, 72, the arm supporting portion 78 and the like from the substrate posture turning region R32 to the above of the substrate holder 65 in the substrate stand-by region R31. Moreover, the Y-direction moving portion 102 of the horizontally moving portion 95 moves the two chucks 71, 72, the arm supporting portion 78 and the like to a second substrate holding position. Here, the second substrate holding position is a position where the twenty-five-paired holding grooves 89, 90 can hold the twenty-five substrates W2 in the second substrate group.

Moreover, the opening and closing portion 87 of the posture turning unit 63 moves the two vertical holders 80, 82 horizontally in a direction where the holders are apart from each other to be opened (see passing position PP3 in FIG. 5).

[Step S17] Receipt of Second Substrate Group by Posture Turning Unit

The substrate holder 65 keeps hold of the twenty-five substrates W2 in the second substrate group in the vertical posture. The lifting member 67 of the lifter LF9 moves the substrate holder 65 upward to an upper position where the substrates W2 can be delivered. At this time, the twenty-five substrates W2 pass a gap between the two vertical holders 80, 82, and are inserted into twenty-five-paired horizontal guide grooves 85, 86 of the fifty-paired horizontal guide grooves 85, 86 individually.

Then, the opening and closing portion 87 moves the two vertical holders 80, 82 horizontally in a direction where the holders are closer to each other to be closed (see holding position PP2 in FIG. 5). Accordingly, the twenty-five substrates W2 held by the substrate holder 65 in the vertical posture are housed with the twenty-five-paired holding grooves 89, 90.

Thereafter, the lifting member 67 of the lifter LF9 moves the substrate holder 65 downward to a lower stand-by position. Accordingly, the twenty-five substrates W2 in the second substrate group are delivered to the posture turning unit 63. That is, the posture turning unit 63 receives the twenty-five substrates W2 in the second substrate group from the substrate holder 65 while holding the sub states W2 with the twenty-five-paired holding grooves 89, 90.

[Step S18] Movement to Substrate Posture Turning Region

Reference is made to FIGS. 10B and 11B. The horizontally moving portion 95 (X-direction moving portion 101 and Y-direction moving portion 102) moves the two chucks 71, 72, the arm supporting portion 78 and the like from the above of the substrate holder 65 in the substrate stand-by region R31 to a predetermined position in the substrate posture turning region R32 while holding the twenty-five substrates W2 with the two vertical holders 80, 82. That is, the posture turning unit 63 transports the twenty-five substrates W2 in the vertical posture to the substrate posture turning region R32.

[Step S19] 180-Degree Rotation of Second Substrate Group by Lateral Rotator

Moreover, the lateral rotator 93 of the posture turning unit 63 rotates the substrates W2 in the vertical posture and the arm supporting portion 78 and the like by 180 degrees around the rotary axis AX4 in the substrate posture turning region R32. Accordingly, device faces indicated by then arrow AR is turned by 180 degrees from leftward Y to rightward Y. Consequently, the device faces of the substrates W2 can be directed upward when such horizontal posture turning is made.

[Step S20] Horizontal Posture Turn of Second Substrate Group by Posture Turning Unit

Reference is made to FIGS. 10C and 11C. Thereafter, the posture turning unit 63 turns a posture of the held twenty-five substrates W2 to horizontal. Specifically, the longitudinal rotator 94 of the posture turning unit 63 rotates the substrates W2, the two chucks 71, 72 and the arm supporting portion 78 by 90 degrees around the horizontal axis AX5 such that the two vertical holders 80, 82 face the center robot CR (see FIG. 1).

Thereafter, the opening and closing portion 87 of the posture turning unit 63 moves the two vertical holders 80, 82 horizontally in a direction where the holders are apart from each other to be opened (see passing position PP3 in FIG. 5). This can pass the substrates W2 between the two vertical holders 80, 82. Moreover, the twenty-five substrates W2 are placed on the twenty-five horizontal guide grooves 85, 86 individually.

Then, the center robot CR takes the twenty-five substrates W2 in the horizontal posture one by one with the two hands 37A, 37B while the substrates W2 pass between the two vertical holders 80, 82 moved into the passing position PP3, and transports the taken substrates W2 to the single-wafer processing chamber SW1. Here, as shown in FIGS. 10C and 11C, the transport mechanism WTR transports next fifty substrates W to the substrate holder 65 of the lifter LF9.

[Step S06] First Single-Wafer Treatment

Description returns to the flowchart in FIG. 6. For example, the center robot CR transports the substrates W (W1, W2) one by one from the posture turning unit 63 to the first single-wafer processing chamber SW1. The first single-wafer processing chamber SW1 supplies deionized water from the nozzle 47 to device faces of the substrates W while the rotating unit 45 rotates the substrates W whose device faces are directed upward. Then, the first single-wafer processing chamber SW1 supplies IPA from the nozzle 47 to the device faces (top faces) of the substrates W to replace the deionized water on the substrates W with the IPA.

[Step S07] Second Single-Wafer Treatment (Dry Treatment)

Thereafter, the center robot CR takes the substrates W, wet with the IPA, from first single-wafer processing chamber SW1, and transports the substrates W to the second single-wafer processing chamber SW2. The second single-wafer processing chamber SW2 performs dry treatment on the substrates W with carbon dioxide under a supercritical state (supercritical fluid). Such dry treatment with the supercritical fluid can suppress collapse of pattern on pattern faces (device faces) of the substrates W.

[Step S08] Substrate Transportation from Buffer Unit to Carrier

The center robot CR transports the substrates W, on which the dry treatment is performed, from the second single-wafer processing chamber SW2 to any mount shelf of the buffer unit 27. When substrates W1 in one lot (twenty-five) are transported into the buffer unit 27, the substrate handling mechanism HTR collectively transports the twenty-five substrates W1 from the buffer unit 27 into an empty first carrier C placed on the shelf 13A. Then, the carrier transport mechanism 11 in the stocker block 3 transports the first carrier C to the load port 9.

Moreover, when substrates W2 in one lot are transported into the buffer unit 27, the substrate handling mechanism HTR collectively transports the twenty-five substrates W2 from the buffer unit 27 into an empty second carrier C placed on the shelf 13A. Then, the carrier transport mechanism 11 in the stocker block 3 transports the second carrier C to the load port 9. An external transport robot, not shown, transports the two carriers C to a next destination in order.

With this embodiment, the second posture turning mechanism 35 includes the substrate holder 65 and the posture turning unit 63. The horizontally moving portion 95 of the posture turning unit 63 can move the arm supporting portion 78 that supports the two horizontal holders 79, 81 and the two vertical holders 80, 82. Moreover, the longitudinal rotator 94 of the posture turning unit 63 rotates the arm supporting portion 78 around the horizontal axis AX5. Accordingly, the posture turning unit 63 can turn the posture of the substrates W that the posture turning unit 63 itself moves and receives.

Moreover, the longitudinal rotator 94 rotates the arm supporting portion 78 around the horizontal axis AX5 so that the two vertical holders 80, 82 face toward the center robot CR in order to turn the posture of the substrates W from vertical to horizontal. Thereafter, the opening and closing portion 87 moves the two vertical holders 80, 82 into the passing position PP3. Accordingly, the center robot CR can transport the substrates W from a side adjacent to the two vertical holders 80, 82.

The posture turning unit 63 includes the lateral rotator 93 configured to rotate the arm supporting portion 78 around the rotary axis AX4 that is orthogonal to the alignment direction of the substrates W (e.g., transverse direction Y) and extends in a direction orthogonal to the horizontal axis AX5. The horizontally moving portion 95 moves the arm supporting portion 78, the lateral rotator 93, the longitudinal rotator 94 and the like horizontally. The posture turning unit 63 can turn a direction of front and back faces of the substrates W at any timing after receiving the substrates W from the substrate holder 65.

Moreover, the two vertical holders 80, 82 include the plural-paired holding grooves 89, 90 for holding the substrates W one by one, and the plural-paired passing grooves 91, 92 for passing the substrates W one by one. The plural-paired holding grooves 89, 90 and the plural-paired passing grooves 91, 92 are arranged alternately in pairs. The two vertical holders 80, 82 are moved to the holding position PP2 by the opening and closing portion 87, whereby the two vertical holders 80, 82 hold a first divided substrate group (twenty-five substrates W1) of the fifty substrates W held by the substrate holder 65 in a vertical posture with the twenty-five-paired holding grooves 89, 90, whereas the two horizontal holders 79, 81 house the first divided substrate group (twenty-five substrates W1). The two vertical holders 80, 82 can hold the first divided substrate group twenty-five substrates (W1) of the fifty substrates W, obtaining a widened pitch between two adjacent substrates W. Accordingly, the center robot CR can take the substrates W from the posture turning unit 63 easily.

Moreover, the horizontally moving portion 95 is positioned higher than the twenty-five substrates W1 (W2) in the vertical posture held by the two vertical holders 80, 82. Contamination due to falling of droplets from the wet substrates W1 (W2) can be prevented in a driving unit, including the horizontally moving portion 95, of the posture turning unit 63. For example, failure due to a contaminated driving unit can be prevented.

Moreover, the horizontal axis AX5 is positioned higher than the twenty-five substrates W1 (W2) in the vertical posture held by the two vertical holders 80, 82. The arm supporting portion 78 supports the two horizontal holders 79, 81 and the two vertical holders 80, 82 via the two horizontal holders 79, 81 from a side opposite to the two vertical holders 80, 82. Accordingly, the substrates W held by the two vertical holders 80, 82 and the like can be moved closer to the center robot CR when the longitudinal rotator 94 rotates the arm supporting portion 78 around the horizontal axis AX5.

Moreover, the posture turning region R3 (containing the second posture turning mechanism 35) is provided between the transferring block 5 and the batch treatment region R1. Moreover, the single-wafer transportation region R4 adjoins the transferring block 5 and the posture turning region R3. Furthermore, the single-wafer treatment region R5 (containing a plurality of single-wafer processing chambers SW1, SW2) adjoins the single-wafer transportation region R4. Moreover, a position of the lifting and lowering board 41 of the center robot CR provided in the single-wafer transportation region R4 is fixed in the horizontal direction XY. Accordingly, the transferring block 5, the second posture turning mechanism 35, the single-wafer processing chambers SW1, SW2 can be arranged around the center robot CR. This can shorten a transportation distance of the substrates W by the center robot CR, for example, resulting in effective transportation of the substrates W. Moreover, the transport mechanism WTR can transports a plurality of substrates W collectively among the substrate delivery position PP in the transferring block 5, the six batch process tanks BT1 to BT6, and the second posture turning mechanism 35. This results in enhanced throughput.

### SECOND EMBODIMENT

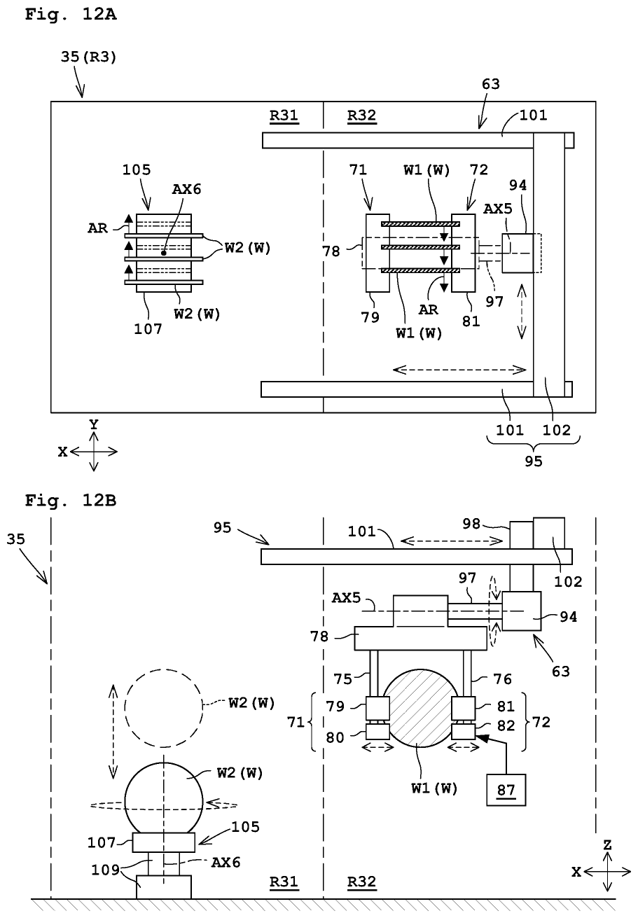

The following describes a second embodiment of the present invention with reference to the drawings. Here, the description common to that of the first embodiment is to be omitted. FIG. 12A is a plan view of a second posture turning mechanism 35 according to the second embodiment. FIG. 12B is a front view of FIG. 12A.

In the first embodiment, the second posture turning mechanism 35 includes the lifter LF9 and the posture turning unit 63 having the lateral rotator 93. In this regard, the second posture turning mechanism 35 in the second embodiment includes a pusher mechanism 105 and a posture turning unit 63 without a lateral rotator 93.

The pusher mechanism 105 holds a plurality of (e.g., fifty) substrates W, transported by the transport mechanism WTR, in a vertical posture. The pusher mechanism 105 includes a pusher 107 and a lifting and rotating portion 109. Here, the pusher 107 corresponds to the substrate holder in the present invention. The lifting and rotating portion 109 corresponds to a second lateral rotator in the present invention.

The pusher 107 holds fifty substrates W, for example, arranged at a predetermined pitch (half pitch) from the below. The pusher 107 includes holding grooves, not shown, whose number is same as the number of substrates W (e.g., fifty) for holding fifty substrates W. The holding grooves of the pusher 107 each have a recess formed in a V-shape. The lifting and rotating portion 109 moves the pusher 107 upward and downward, and rotates the pusher 107 around a vertical axis AX6. The lifting and rotating portion 109 includes one electric motor, or two or more electric motors, for example.

As shown in FIG. 12B, the posture turning unit 63 in the second embodiment does not include the lateral rotator 93 shown in FIG. 4B. Accordingly, a distal end of the rotation shaft 97 is fixed to the arm supporting portion 78.

The following describes operation of the second posture turning mechanism 35 in the second embodiment with reference to the flowchart in FIG. 7. The second posture turning mechanism 35 operates basically in such a manner as in the flowchart of FIG. 7. However, since the second posture turning mechanism 35 in the second embodiment does not include the lateral rotator 93, the step S19 in FIG. 7 is not performed. Instead of this, the pusher mechanism 105 rotates twenty-five substrates W2 in a second substrate group around a vertical axis AX6.

In the step S13 in FIG. 7, the posture turning unit 63 takes out the twenty-five substrates W1 of the fifty substrates W from the substrate holder 65 while holding the substrates W1 with the two vertical holders 80, 82 (twenty-five-paired holding grooves 89, 90).

Thereafter, the lifting and rotating portion 109 of the pusher mechanism 105 rotates the twenty-five substrates W2, held by the pusher 107, by 180 degrees around the vertical axis AX6. Consequently, when a posture of the substrates W2 in the second substrate group is turned, device faces of the substrates W2 can be directed upward, which is similar to the substrates W1 in the first substrate group. In addition, the vertical axis AX6 is set in the center of the fifty substrates W, held by the pusher 107, in plan view. Accordingly, 180-degree rotation shifts a position of the substrates W2 in the alignment direction of the substrates W by a half pitch. Accordingly, the two vertical holders 80, 82 can hold the substrates W2 in the second substrate group at the same position as the first substrate holding position where twenty-five-paired holding grooves 89, 90 can hold the substrates W1 in the first substrate group. Moreover, the horizontally moving portion 95 may move the two vertical holders 80, 82 and the like to the first substrate holding position and the second substrate holding position.

Thereafter, in the step S17 in FIG. 7, the posture turning unit 63 holds and transports the twenty-five substrates W2 to which 180-degree rotation is made. However, the step S19 in FIG. 7 is not performed in the second embodiment.

With this embodiment, the lifting and rotating portion 109 of the pusher mechanism 105 rotates the pusher 107 around the vertical axis AX6. Accordingly, the posture turning unit 63 does not necessarily include the lateral rotator 93 in the first embodiment, and the directions of the front and back faces of the substrates W can be turned at a side adjacent to the pusher 107, leading to a simplified construction of the posture turning unit 63.

### THIRD EMBODIMENT

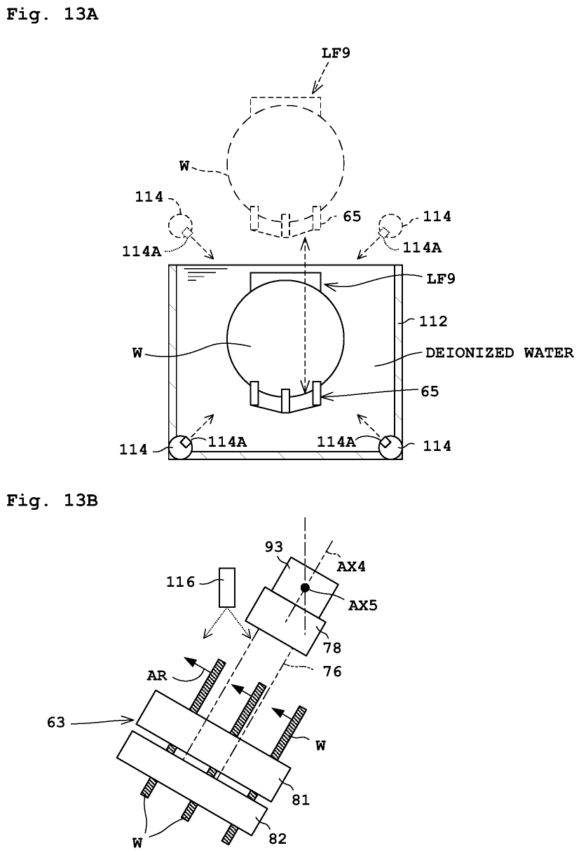

The following describes a third embodiment of the present invention with reference to the drawings. Here, the description common to that of the first and second embodiments is to be omitted. FIG. 13A is a longitudinal sectional view of a lifter LF9 of a second posture turning mechanism 35 according to the third embodiment. FIG. 13B is a side view of a posture turning unit 63 of the second posture turning mechanism 35 according to the third embodiment.

Reference is made to FIG. 13A. The second posture turning mechanism 35 in the third embodiment includes a stand-by tank 112 for storing a liquid and two jet pipes 114 for supplying deionized water (DIW) as a liquid, for example, to the stand-by tank 112 in order to immerse substrates W held by a substrate holder 65 in the liquid when the substrate holder 65 of the lifter LF9 moves downward. The jet pipe 114 is configured to extend linearly in the front-back direction X or transverse direction Y. The jet pipe 114 has a plurality of jet ports 114A (nozzles for holders) in a direction where the jet pipe 114 extends. The jet ports 114A each ejects deionized water. The stand-by tank 112 stores deionized water ejected from the jet pipes 114.

As shown in FIG. 8C, for example, while the posture turning unit 63 turns a posture of the substrates W1, the substrates W2 at a stand-by state are immersed in the deionized water within the stand-by tank 112, leading to prevention of drying of the substrates W2.

Note that the stand-by tank 112 does not necessarily store deionized water. In this case, the jet ports 114A of the jet pipe 114 may supply deionized water in a shower state or a mist state to the substrates W held by the substrate holder 65. In addition, as shown in dotted lines in FIG. 13A, the jet ports 114A (jet pipe 114) may be located at a position higher than the substrates W. When the deionized water in a shower state or a mist state is supplied to the substrates W, the stand-by tank 112 may or may not be provided.

Reference is next made to FIG. 13B. The second posture turning mechanism includes a nozzle 116. The nozzle 116 supplies deionized water (DIW) as a liquid in a shower state or a mist state to the substrates W held by the vertical holders 80, 82 of the posture turning unit 63. The nozzle 116 is provided at a position higher than the substrates W. Moreover, the nozzle 116 may be movable so as not to interfere with the posture turning unit 63.

For example, the longitudinal rotator 94 turns a posture of the substrates W, held by the vertical holders 80, 82, to either vertical or oblique. In this condition, the nozzle 116 supplies deionized water in a shower state or a mist state to the substrates W held by the vertical holders 80, 82. Here, the oblique posture is a posture where device faces of the substrates are directed upward.

For example, when the center robot CR suspends transportation of the substrates W, drying of the substrates W held by the posture turning unit 63 can be prevented. Moreover, if the posture of the substrates W is horizontal in supplying the deionized water, the deionized water in a shower state or a mist state is hard to spread over the device faces. However, the posture of the substrates W is turned to either vertical or oblique where the device faces are directed upward, leading to easy spread of the deionized water in a shower state or a mist state over the device faces.

Moreover, the substrate treating apparatus 1 may adopt both the construction in FIG. 13A and the construction in FIG. 13B. Alternatively, the substrate treating apparatus 1 may adopt either the construction in FIG. 13A or the construction in FIG. 13B. Moreover, the nozzle 116 corresponds to the nozzle for the posture turning unit in the present invention.

If the substrates W are dried before the dry treatment in the single-wafer processing chamber SW2, pattern collapse of the substrates W occurs. However, this embodiment can prevent drying of the substrates W held by the pusher 107. Moreover, this embodiment can prevent drying of the substrates W held by the two vertical holders 80, 82 of the posture turning unit 63.

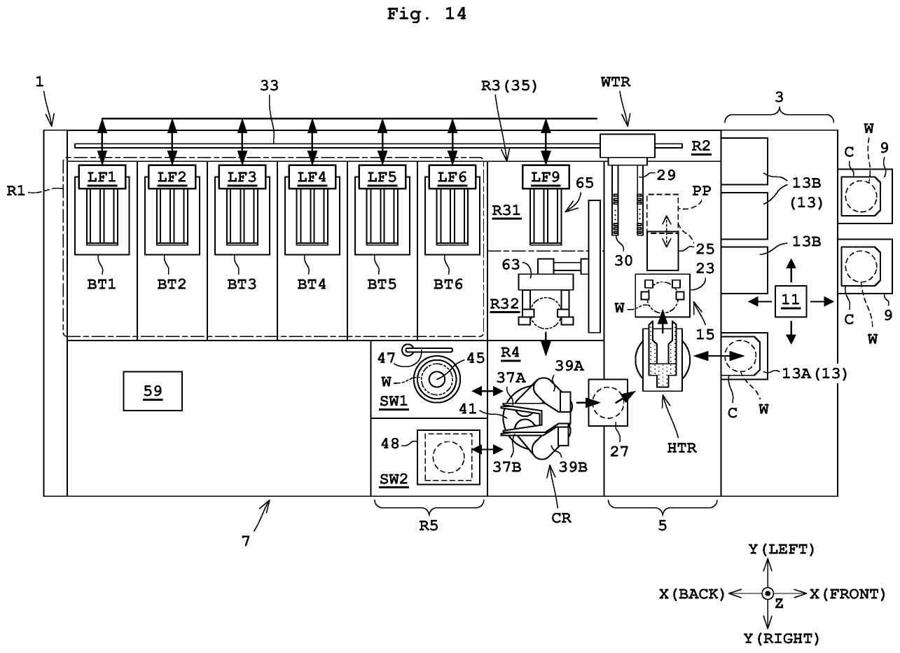

The present invention is not limited to the foregoing examples, but may be modified as follows.
(1) In the embodiments described above, the substrate stand-by region R31 of the second posture turning mechanism 35 adjoins the batch treatment region R1 and the substrate posture turning region R32 adjoins the transferring block 5 in FIG. 1, for example. That is, the substrate stand-by region R31 and the substrate posture turning region R32 of the second posture turning mechanism 35 are arranged in the front-back direction X. In this regard, the substrate stand-by region R31 and the substrate posture turning region R32 may be arranged in the transverse direction Y as shown in FIG. 14.
In this case, the substrate posture turning region R32 is arranged leftward Y of the single-wafer transportation region R4. The substrate stand-by region R31 is arranged leftward Y of the substrate posture turning region R32.
(2) In the embodiments and the modification described above, the batch process tanks BT1 to BT6 each perform treatment on the fifty substrates W arranged in a face-to-face system and at a half pitch. In this regard, the batch process tanks BT1 to BT6 may each perform treatment on the substrates W arranged in a face-to-back system where device faces of the substrates W are all directed to the same direction. The batch process tanks BT1 to BT6 may each perform treatment on twenty-five substrates W for one carrier C arranged at a full pitch. When fifty substrates W are arranged in the face-to-back system in FIG. 11B, the Y-direction moving portion 102 moves the two chucks 71, 72 in the transverse direction Y where the substrates W are aligned. That is, the Y-direction moving portion 102 moves the two chucks 71, 72 between the first substrate holding position and the second substrate holding position. Accordingly, the posture turning unit 63 can pick up twenty-five substrates W1 or twenty-five substrates W2.
(3) In the embodiments and the modifications described above, the single-wafer processing chamber SW2 performs the dry treatment on the substrates W with the supercritical fluid. In this regard, the single-wafer processing chamber SW2 may include a rotating unit 45 and a nozzle 47 like the single-wafer processing chamber SW1. In this case, the single-wafer processing chambers SW1, SW2 each supply deionized water and IPA to the substrates W in this order, for example, and then perform dry treatment (spin drying) on the substrates W.
(4) In the embodiments and the modifications described above, the lifting member 67 as a relative lifting member moves the substrate holder 65 upward and downward when the posture turning unit 63 receives the substrates W from the substrate holder 65 in the step S13, for example. In this regard, such a configuration is adoptable that the posture turning unit 63 includes the lifting member for moving the two chucks 71, 72, the arm supporting portion 78 and the like, thereby receiving the substrates W from the substrate holder 65. Moreover, when the posture turning unit 63 receives the substrates W from the substrate holder 65, the lifting member of the posture turning unit 63 and the lifting member 67 may be moved upward and downward together.
(5) In the embodiments and the modifications described above, the opening and closing portion 87 moves the two vertical holders 80, 82 linearly in the horizontal direction. In this regard, the opening and closing portion 87 may swing the two vertical holders 80, 82.

The present invention may be embodied in other specific forms without departing from the spirit or essential attributes thereof and, accordingly, reference should be made to the appended claims, rather than to the foregoing specification, as indicating the scope of the invention.

What is claimed is:

1. A substrate treating apparatus for successively performing batch treatment for processing a plurality of substrates collectively and single-wafer treatment for processing the substrates one by one, the substrate treating apparatus comprising:
a batch process tank configured to perform treatment on the plurality of substrates collectively;
a batch substrate transport mechanism configured to transport the substrates in a vertical posture collectively to the batch process tank;
a single-wafer processing chamber configured to perform treatment on the substrates one by one;
a horizontal substrate transport mechanism configured to transport the substrates in a horizontal posture one by one to the single-wafer processing chamber; and
a posture turning mechanism configured to turn a posture of the substrates, on which the batch treatment is performed, from vertical to horizontal,
the posture turning mechanism including:
a substrate holder configured to hold the substrates in the vertical posture that are transported by the batch substrate transport mechanism and arranged at a predetermined pitch; and
a posture turning unit configured to receive the substrates from the substrate holder and turn a posture of the substrates from vertical to horizontal, the posture turning unit including:
two horizontal holders configured to house two sides of each of the substrates opposite to each other in a radial direction and place the substrates thereon at the predetermined pitch when the substrates are in the horizontal posture;
two vertical holders configured to house two sides of each of the substrates, and provided below the horizontal holders and configured to hold the substrates in the vertical posture when the substrates are in the vertical posture;
an opening and closing portion configured to move the two vertical holders between a holding position where a gap between the two vertical holders is narrowed for holding the substrates with the two vertical holders and a passing position where the gap between the two vertical holders is widened for passing the substrates through the two vertical holders;
a supporting portion configured to support the two horizontal holders and the two vertical holders;
a longitudinal rotator configured to rotate the supporting portion around a horizontal axis so as to direct the two vertical holders to the horizontal substrate transport mechanism in order to turn the posture of the substrates from vertical to horizontal; and
a moving unit configure to move the supporting portion and the longitudinal rotator between a substrate stand-by region where the substrate holder is arranged and a substrate posture turning region for turning the posture of the substrates from vertical to horizontal,
the moving unit moving the supporting portion and the longitudinal rotator to the substrate stand-by region when the substrates in the vertical posture are held by the substrate holder,
the two vertical holders being moved to the holding position by the opening and closing portion, whereby the two vertical holders hold the substrates in the vertical posture held by the substrate holder, whereas the two horizontal holders house the substrates held by the two vertical holders,
the moving unit moving the supporting portion and the longitudinal rotator to the substrate posture turning region while the substrates are held by the two vertical holders,
the longitudinal rotator rotating the supporting portion around the horizontal axis, thereby turning the posture of the substrates from vertical to horizontal,
the opening and closing portion moving the two vertical holders into the passing position when the posture of the substrates is turned to horizontal, and
the horizontal substrate transport mechanism taking the substrates in the horizontal posture one by one while the substrates pass between the two vertical holders moved into the passing position, and transporting the taken substrates to the single-wafer processing chamber.

2. The substrate treating apparatus according to claim 1, wherein
the posture turning unit further includes a lateral rotator configured to rotate the supporting portion around a rotary axis that is orthogonal to an alignment direction of the substrates and extends in a direction orthogonal to the horizontal axis, and
the moving unit moves the supporting portion, the lateral rotator, and the longitudinal rotator.

3. The substrate treating apparatus according to claim 1, wherein
the posture turning mechanism further includes a second lateral rotator configured to rotate the substrate holder around a vertical axis.

4. The substrate treating apparatus according to claim 1, wherein
the two vertical holders include plural-paired holding grooves for holding the substrates one by one and plural-paired passing grooves for passing the substrates one by one,
the plural-paired holding grooves and the plural-paired passing grooves are arranged alternately in pairs, and
the two vertical holders are moved to the holding position by the opening and closing portion, whereby a first divided substrate group, made by taking every other substrate out of the substrates held by the substrate holder in the vertical posture, is held with the plural-paired holding grooves, and the two horizontal holders house the first divided substrate group.

5. The substrate treating apparatus according to claim 1, wherein
the posture turning mechanism further includes a stand-by tank configured to store a liquid in which the substrates held by the substrate holder is immersed.

6. The substrate treating apparatus according to claim 1, wherein
the posture turning mechanism further includes a nozzle for the posture turning unit configured to supply a liquid in a shower state or in a mist state to the substrates held by the two vertical holders of the posture turning unit.

7. The substrate treating apparatus according to claim 1, wherein
the moving unit is positioned higher than the substrates in the vertical posture held by the two vertical holders.

8. The substrate treating apparatus according to claim 1, wherein
the horizontal axis is positioned higher than the substrates in the vertical posture held by the two vertical holders, and
the supporting portion supports the two horizontal holders and the two vertical holders via the two horizontal holders from a side opposite to the two vertical holders.
